(19) United States
(12) Patent Application Publication
(10) Pub. No.: US 2017/0261561 A1
(43) Pub. Date: Sep. 14, 2017

(54) DEVICE AND METHOD FOR COMPUTING RESIDUAL CAPACITY OF CELL, AND RECORDING MEDIUM

(71) Applicant: NEC Corporation, Tokyo (JP)

(72) Inventors: Yuichi IMAMURA, Tokyo (JP); Junichi MIYAMOTO, Tokyo (JP); Shingo TAKAHASHI, Tokyo (JP); Sho OHTANI, Tokyo (JP)

(73) Assignee: NEC Corporation, Tokyo (JP)

(21) Appl. No.: 15/509,647

(22) PCT Filed: Sep. 8, 2015
(86) PCT No.: PCT/JP2015/004545

§ 371 Date: Mar. 8, 2017

(30) Foreign Application Priority Data
Sep. 11, 2014 (JP) 2014-185039

(51) Int. Cl. G01R 31/36; H01M 10/48; H02J 7/00

(52) U.S. Cl. CPC G01R 31/3624; H02J 7/0052; H01M 10/48

(57) ABSTRACT

Through the present invention, a residual capacity is measured with good precision even when a system for calculating the residual capacity of a storage cell on the basis of voltage and a system for calculating the residual capacity of a storage cell according to current integration are combined. In the present invention, as a first differential residual capacity, a difference value is calculated between a first residual capacity indicating the residual capacity of a storage cell at a first time, calculated by a voltage estimation system from the voltage and current of the storage cell at the first time, and the residual capacity of the storage cell at a second time, calculated by a voltage estimation system from the voltage and current from the storage cell at the second time. A second differential residual capacity is then calculated indicating the difference value between the residual capacity of the storage cell at the first time and the residual capacity of the storage cell at the second time, by a current integration system, on the basis of the integrated amount of current in the period between the first time and the second time. A current increase/decrease range indicating the increase/decrease of the current from the current at the first time and the current at the second time is then calculated, the first differential residual capacity or the second differential residual capacity is switched as the differential residual capacity on the basis of the current increase/decrease range, and the sum of the first residual capacity and the switched differential residual capacity is outputted as the residual capacity of the storage cell at the second time.

### TECHNICAL FIELD

The present invention relates to a device and a method for computing a cell remaining charge and a recording medium, in particular to a device and a method for computing a cell remaining charge and a recording medium for measuring the remaining charge of a storage cell.

### BACKGROUND ART

Recently, due to the improvement of energy density of secondary batteries, storage cells such as a lithium ion battery have come to be widely utilized. Improvement in volumetric energy density which is the energy density per unit volume of the storage cell, and reduction in power consumption of devices have achieved miniaturization and high performance of portable devices such as mobile phones. In addition, improvement in weight energy density which is energy density per unit weight of the storage cell, achieves extending travel distance of electric vehicles and the like. Further, stationary storage cells are beginning to be utilized in ordinary homes, such that the storage cell covers power consumption during the day time by charge lower cost power in nighttime.

Generally, the battery capacity of the storage cell decreases by discharging, and increases by charging. In the case of the electric vehicle for example, the remaining energy of the storage cell decreases by driving the vehicle, and the remaining travel distance is accordingly reduced. In the case of the home-use storage cell, the remaining energy of the storage cell decreases by cover power consumption of a cleaner, a washing machine, a TV set and the like.

The remaining energy of the storage cell may be expressed by SOC (state of charge), representing the ratio of the amount of charged electricity to the electrical capacity of the storage cell. In the case of the home-use storage cell, the remaining energy of the storage cell is notified to the user by an LED (light emitting diodes) of the indicator turning off according to the decrease of the SOC. In the case of the electric vehicle, the remaining travel distance or the like is calculated from the SOC, to be notified to the user.

To calculate the SOC of the storage cell, normally the current flowing or received from the storage cell is measured with a current sensor or the like, and the time-integrated current value is divided by the full charge capacity of the storage cell to calculate the SOC. In recent years, a method (for example, equivalent circuit method) is employed, in which an open circuit voltage is estimated from a terminal voltage (cell voltage) using an equivalent circuit model simulating a battery or an adaptive digital filter, and the SOC is calculated from the estimated open circuit voltage. Further, techniques for resolving a drawback in the former method that error is accumulated through the current integration, and a drawback in the latter method that the SOC accuracy is deteriorated due to transient current, have been proposed. On the basis of such solution techniques, a method for improving the accuracy of the SOC have been proposed the method using current integration method and the equivalent circuit method according to circumstances.

Patent Literature 1 discloses a technique of specifically defining a switching timing at a prescribed timing, the switching timing being a key issue in the method for switching the SOC calculated by the current integration method and the SOC calculated by the equivalent circuit method. According to Patent Literature 1, the SOC calculated by the equivalent circuit method is switched to the SOC calculated by the current integration method, when a large current runs or when abrupt current fluctuation is imposed on the battery. With the mentioned technique, the SOC is switched when the error between the voltage estimation value by the equivalent circuit method and the actual voltage acquired from a voltage sensor is not larger than a prescribed value, and the actual current and the actual current fluctuation value during a prescribed period is not larger than a prescribed value, and the battery temperature is not lower than a prescribed value.

Patent Literature 2 discloses a technique for calculating the remaining energy with high accuracy by utilizing the advantages of both the remaining energy based on the current integration and the remaining energy based on the estimation value of the open circuit voltage by the equivalent circuit method, in consideration of both the charge/discharge status of the energy storage device and the state of an electric load connected to the energy storage device. According to this technique, the remaining energy based on the current integration and the remaining energy based on the estimation value of the open circuit voltage are weighting and synthesized, to calculate a resultant remaining energy. As the weight, either one of the current changing rate of the charge/discharge current of the energy storage device or the state of use of the electric load connected to the energy storage device may be utilized.

### CITATION LIST

### Patent Literature

[Patent Literature 1] Published patent application No. 2011-106952

[Patent Literature 2] U.S. Pat. No. 4,638,211

### SUMMARY OF INVENTION

### Technical Problem

Patent Literature 1 intends to keep high SOC detection accuracy, by switching from the SOC calculated by the equivalent circuit method to the SOC calculated by the current integration method when a large current flows or abrupt current fluctuation is occurred on the battery. Generally, it is widely known that abrupt current fluctuation deteriorates the accuracy of the SOC calculation based on the equivalent circuit method. In the case of the current integration method, however, the integration error is increased because errors of the current sensor are accumulated during the period of the current integration. Therefore, adopting Patent Literature 1 does not provide sufficient accuracy of the SOC, because the SOC contains the integration error accumulated as it is up to the time point when the SOC is switched to the SOC calculated by the current integration method. Accordingly, it is desirable to use the SOC based on the equivalent circuit method, whenever possible. Regarding the absolute value of the current, for example, although abrupt current fluctuation may be involved with a voltage drop due to internal resistance, the equivalent circuit method provides higher accuracy of the SOC than the accuracy of the SOC calculated by the current integration method, if parameter estimation of the equivalent circuit or gain adjustment are properly performed.

According to Patent Literature 2, the remaining energy based on the current integration method and the remaining energy based on the estimation value of the open circuit voltage estimated form the internal impedance are weighted and synthesized. In the weighted synthesis, the ratio of the remaining energy based on the current integration method is flexibly added depending on the fluctuation amount of the transient current. This is intended to suppress the deteriorated in calculation accuracy of the remaining energy based on the open circuit voltage caused by the abrupt fluctuation of the transient current. However, the remaining energy based on the current integration method often contains a large number of error, such as accumulated reading errors of the current sensor and accumulated offset errors. Therefore, the accuracy of the resultant calculation of remaining energy may be reduced by use of the value obtained by weighting the remaining energy containing such large number of error.

An object of the present invention is to provides a device and a method for cell remaining energy computation, and a recording medium, that enable the remaining energy to be measured with high accuracy, even if combining the calculation method of the remaining energy of the storage cell based on the voltage and the calculation method of the remaining energy of the storage cell based on the current integration.

### Solution to Problem

To achieve the above-described object, a cell remaining energy computation device according to one aspect of the present invention is a cell remaining energy computation device that acquires a voltage and a current from a storage cell at a prescribed time period, and the device comprises: first computing means that calculates, as a first differential remaining energy, a differential value between a first remaining energy representing a remaining energy of the storage cell at a first time calculated by a voltage estimate method from the voltage and the current of the storage cell acquired at the first time, and a remaining energy of the storage cell at a second time calculated by the voltage estimate method from the voltage and the current of the storage cell acquired at the second time; second computing means that calculates a second differential remaining energy representing a differential value between the remaining energy of the storage cell at the first time and the remaining energy of the storage cell at the second time, by a current integration method from a current amount integrated during a period between the first time and the second time; and third computing means that calculates a current range indicating an increase or a decrease of the current, on a basis of the current at the first time and the current at the second time, selects one of the first differential remaining energy or the second differential remaining energy as a differential remaining energy on the basis of the current range, and outputs a sum of the first remaining energy and the selected differential remaining energy, as the remaining energy of the storage cell at the second time.

A cell remaining energy computation method according to another aspect of the present invention is a cell remaining energy computation method for acquiring a voltage and a current from a storage cell at a prescribed time period, and the method comprises: calculating, as a first differential remaining energy, a differential value between a first remaining energy representing a remaining energy of the storage cell at a first time calculated based on a voltage estimate method from the voltage and the current of the storage cell acquired at the first time, and a remaining energy of the storage cell at a second time calculated by the voltage estimate method from the voltage and the current of the storage cell acquired at the second time; calculating a second differential remaining energy representing a differential value between the remaining energy of the storage cell at the first time and the remaining energy of the storage cell at the second time, by a current integration method from a current amount integrated during a period between the first time and the second time; and calculating a current range indicating an increase or a decrease of the current, on a basis of the current at the first time and the current at the second time, selecting one of the first differential remaining energy or the second differential remaining energy as a differential remaining energy on the basis of the current range, and outputting a sum of the first remaining energy and the selected differential remaining energy, as the remaining energy of the storage cell at the second time.

A computer-readable recording medium containing a cell remaining energy computation program according to still another aspect of the present invention is a computer-readable recording medium containing a cell remaining energy computation program for acquiring a voltage and a current from a storage cell at a prescribed time period, and the program is configured to cause a computer to act as: first computing functional means that calculates, as a first differential remaining energy, a differential value between a first remaining energy representing a remaining energy of the storage cell at a first time calculated by a voltage estimate method from the voltage and the current of the storage cell acquired at the first time, and a remaining energy of the storage cell at a second time calculated by the voltage estimate method from the voltage and the current of the storage cell acquired at the second time; second computing functional means that calculates a second differential remaining energy representing a differential value between the remaining energy of the storage cell at the first time and the remaining energy of the storage cell at the second time, by a current integration method from a current amount integrated during a period between the first time and the second time; and third computing functional means that calculates a current range indicating an increase or a decrease of the current, on a basis of the current at the first time and the current at the second time, selects one of the first differential remaining energy or the second differential remaining energy as a differential remaining energy on a basis of the current range, and outputs a sum of the first remaining energy and the selected differential remaining energy, as the remaining energy of the storage cell at the second time.

### Advantageous Effect of Invention

The present invention enables the remaining energy to be calculated with high accuracy, despite combining the calculation method of the remaining energy of the storage cell based on the voltage and the calculation method of the remaining energy of the storage cell based on the current integration.

### BRIEF DESCRIPTION OF DRAWINGS

FIG. 1 is a block diagram showing a configuration of a cell remaining energy computation device according to a first embodiment of the present invention;

FIG. 2 is a flowchart showing steps of processing of a cell remaining energy computation method according to the first embodiment of the present invention;

FIG. 3 is a block diagram showing an example of hardware configuration of the cell remaining energy computation device according to the first embodiment of the present invention;

FIG. 4 is a block diagram showing a configuration of functional means realized by a computer-readable recording medium containing a program according to the first embodiment of the present invention;

FIG. 5 is a block diagram showing a configuration of a cell remaining energy computation device according to a second embodiment of the present invention;

FIG. 6 is a flowchart showing steps of the processing of a cell remaining energy computation method according to the second embodiment of the present invention;

FIG. 7 is a block diagram showing a configuration of functional means realized by a computer-readable recording medium containing a program according to the second embodiment of the present invention;

FIG. 8 is a block diagram showing a configuration of a cell remaining energy computation device according to a third embodiment of the present invention;

FIG. 9 is a graph showing a prescribed correlation between current range and temperature, for obtaining a loading rate of ΔSOCi;

FIG. 10 is a diagram showing an example of discharge pattern in remaining energy measurement;

FIG. 11 is a flowchart showing steps of processing of a cell remaining energy computation method according to the third embodiment of the present invention;

FIG. 12 is a diagram showing differences in error relative to an SOC true value between cell remaining energy computation according to a current integration method, a voltage estimate method, and a method according to related art, and a cell remaining energy computation according to the third embodiment of the present invention;

FIG. 13 is a block diagram showing a configuration of a cell remaining energy computation device according to a fourth embodiment of the present invention;

FIG. 14 is a flowchart showing steps of processing of a cell remaining energy computation method according to the fourth embodiment of the present invention;

FIG. 15 is a graph showing a prescribed correlation between temperature and a loading rate of an preceding cycle, for obtaining a converging time until deteriorated in accuracy due to abrupt current fluctuation in the voltage estimate method is converged; and

FIG. 16 is a diagram showing differences in error relative to an SOC true value between cell remaining energy computation based on a current integration method, a voltage estimate method, and a method according to related art, and a cell remaining energy computation according to the fourth embodiment of the present invention.

### DESCRIPTION OF EMBODIMENTS

Hereafter, embodiments of the present invention will be described with reference to the drawings.

The embodiments merely represent examples, and configurations of disclosed devices or the like are not limited to those according to the following embodiments. Directions of arrows in the drawings are also merely exemplary, and not intended to limit the directions of signals between blocks.

In the calculation method of the SOC of a storage cell of the description of the embodiments, the SOC in the fully charged state immediately after recharging will be referred to as initial value of SOC, and a method of estimating the SOC by integrating the charge/discharge current will be referred to as current integration method. In addition, a method of calculating the SOC base on a terminal voltage (cell voltage) of the storage cell, different from the current integration method, will be referred to as voltage estimate method.

The voltage estimate method includes the method of calculating the SOC from a map on which the terminal voltage, and the method of calculating the SOC from an estimated open circuit voltage obtained by estimating the open circuit voltage in an unloaded state from the terminal voltage. Further, examples of the open circuit voltage estimate method include the method of estimating the open circuit by adding or subtracting a voltage drop at the time of flowing the current from the calculated internal resistance which is calculated from the terminal voltage and the current and also the method of estimating the open circuit voltage utilizing an equivalent circuit model of the cell or an adaptive digital filter.

### Definition of Terms

The term “time period” herein indicates to a minimum value of intervals between a plurality of timings (e.g., time of day, or time point) to acquire the voltage and the current from the storage cell. For example, in the case of acquiring the voltage and the current at regular intervals, such as a first time, a second time, a third time, and so forth, the time period indicates to the interval between the first time and the second time, the interval between the second time and the third time, and so forth. As will be subsequently described herein, the timing (e.g., time of day, or time point and so forth) will hereinafter be expressed as first time, second time, time k, time k−1, time k+1, and so forth.

The term “preceding cycle” herein indicates the time k for the time k+1, when the voltage and the current are acquired at regular intervals, for example, the voltage and the current are acquired at the time k−1, the time k, the time k+1, and so forth. The time k−1 for the time k may also be indicated as “preceding cycle”.

The term “period for the most recent one cycle” herein indicates a period between a latest acquisition timing and the acquisition timing of the preceding cycle for latest acquisition timing, among the timings (e.g., time of day, or time point) to acquire the voltage and the current. For example, when the latest acquisition timing is the time k+1, the period for the most recent one cycle indicate the period between the time k+1 and the time k that is preceding cycle for the time k+1.

The embodiments of the present invention relate to the calculation of the cell remaining energy. In the embodiments of the present invention, a first remaining energy, representing the remaining energy of the storage cell at the first time, is calculated from the voltage and the current of the storage cell acquired at the above described first time by a voltage estimate method. Then a differential value between the first remaining energy and a remaining energy of the storage cell at the second time is calculated as a first differential remaining energy, the battery capacity of the storage cell at the second time being calculated from the voltage and the current of the storage cell acquired at the above described second time by the voltage estimate method. Further, a second differential remaining energy is calculated based on an integrated value of current during the period between the first time and the second time, the second differential remaining energy indicating a differential value between the remaining energy of the storage cell at the first time and the remaining energy of the storage cell at the second time.

Further, a current range indicating an increase or decrease of the current is calculated from the current at the first time and the current at the second time. According to the calculated current range, the first differential remaining energy or the second differential remaining energy is switched to be the differential remaining energy. For example, when the current range during the period between the first time and the second time is small, the first differential remaining energy is selected as the differential remaining energy. In contrast, when the current range during the period between the first time and the second time is large, the second differential remaining energy is selected as the differential remaining energy. Then the sum of the first remaining energy and the selected differential remaining energy is outputted as the remaining energy of the storage cell at the second time.

For example, when the current range during the period between the first time and the second time is large, the second differential remaining energy is selected as the differential remaining energy. When the current range during the period between the first time and the second time is small, the first differential remaining energy is selected as the differential remaining energy. Such arrangements enable the cell remaining energy to be calculated with high accuracy, despite combining the calculation method of the remaining energy of the storage cell based on the voltage and the calculation method of the remaining energy of the storage cell based on the current integration. Hereunder, specific embodiments of the present invention will be described with reference to the drawings.

### First Embodiment

A configuration of a cell remaining energy computation device according to a first embodiment will be described hereunder.

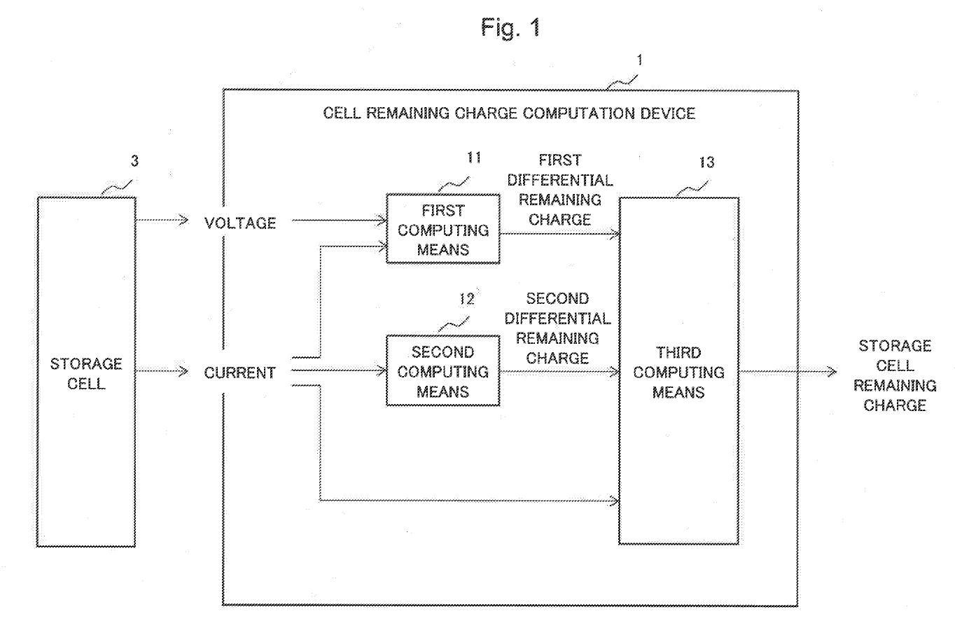

FIG. 1 is a block diagram showing a configuration of the cell remaining energy computation device according to the first embodiment of the present invention.

The cell remaining energy computation device 1 in the first embodiment acquires the voltage and the current from a storage cell 3, at a prescribed time period. The cell remaining energy computation device 1 includes first computing means 11 that calculates the remaining energy of the storage cell 3 by the voltage estimate method, and second computing means 12 that calculates the remaining energy of the storage cell 3 by the current integration method. The cell remaining energy computation device 1 further includes third computing means 13 that appropriately selects one of the remaining energy calculated by the voltage estimate method and the remaining energy calculated by the current integration method, to thereby outputting a resultant remaining energy.

The first computing means 11 receives an input of the voltage and the current acquired from the storage cell 3 at the prescribed time period, and calculates the remaining energy of the storage cell 3 by the voltage estimate method, as the first remaining energy. For example, the first computing means 11 calculates the first remaining energy, indicating the remaining energy of the storage cell 3 at the first time, by the voltage estimate method from the voltage and the current which are acquired from the storage cell 3 at the first time. Then the first computing means 11 calculates the remaining energy of the storage cell 3 at the second time, by the voltage estimate method from the voltage and the current which are acquired from the storage cell 3 at the second time. The first computing means 11 calculates, as the first differential remaining energy, a differential value with the first remaining energy which is calculated by the voltage estimate method based on the voltage at the preceding cycle and the current acquired at the preceding cycle. More specifically, the first computing means 11 calculates the differential value, as the first differential remaining energy, between the first remaining energy and the remaining energy of the storage cell 3 at the second time, the remaining energy being calculated by the voltage estimate method from the voltage and the current which are acquires from the storage cell 3 at the second time.

The second computing means 12 receives an input of the current acquired from the storage cell 3 at the mentioned time period, and calculates the remaining energy of the storage cell 3 by the current integration method as the second differential remaining energy, on the basis of the integrated amount of current during a period for the most recent one cycle. More specifically, the second computing means 12 calculates the second differential remaining energy by the current integration method based on the integrated amount of the current during the period between the first time and the second time, the second different remaining energy indicating the differential value between the remaining energy of the storage cell 3 at the first time and the remaining energy of the storage cell 3 at the second time.

The third computing means 13 receives an input of the current acquired from the storage cell 3 at the mentioned time period, and calculates the current range indicating the increase or decrease of the current during the period for the most recent one cycle. Here, period for the most recent one cycle indicates, for example, the period between the first time and the second time. The third computing means 13 selects one of the first differential remaining energy or the second differential remaining energy as the differential remaining energy of the corresponding cycle, depending on the current range. Then the third computing means 13 adds the differential remaining energy of the corresponding cycle to the remaining energy of the storage cell 3 outputted during the preceding cycle, and outputs the result as the remaining energy of the storage cell 3 of the corresponding cycle. More specifically, the third computing means 13 outputs the sum of the first remaining energy and the selected differential remaining energy, as the remaining energy of the storage cell 3 at the second time.

Hereunder, a cell remaining energy computation method according to the first embodiment will be described.

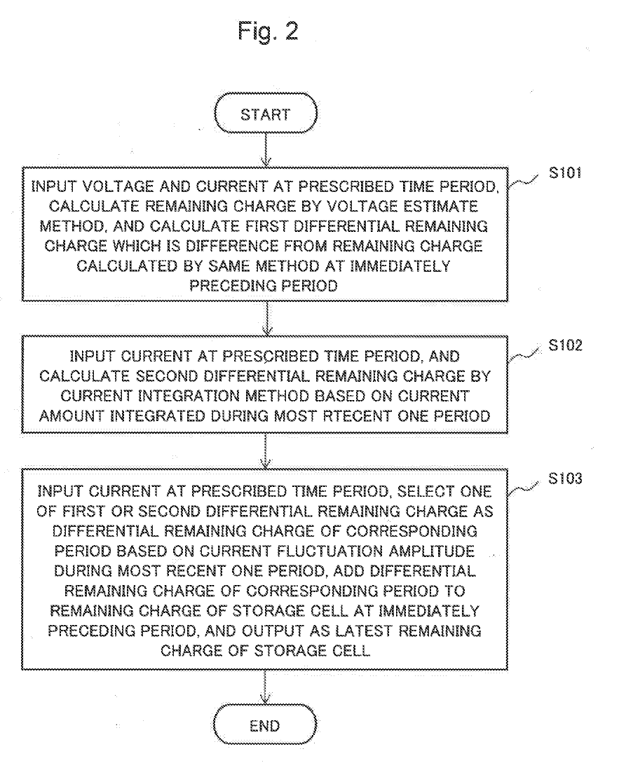

FIG. 2 is a flowchart showing steps of processing of the cell remaining energy computation method of the first embodiment of the present invention.

The cell remaining energy computation method of the first embodiment is processed by including a first differential remaining energy computation step (S101), a second differential remaining energy computation step (S102), and a storage cell remaining energy computation step (S103).

The first differential remaining energy computation step includes receiving the input of the voltage and the current which are acquired from the storage cell at a prescribed time period, and calculating the remaining energy of the storage cell by the voltage estimate method, as the first remaining energy. This step further includes calculating, as the first differential remaining energy, the differential value with respect to the first remaining energy calculated by the voltage estimate method from the voltage and the current which are acquired at the preceding cycle (S101).

More specifically, at the first differential remaining energy computation step, for example, the first remaining energy is calculated from the voltage and the current of the storage cell at the first time by the voltage estimate method, first remaining energy indicating the remaining energy of the storage cell at the first time. Then the remaining energy of the storage cell at the second time is calculated by the voltage estimate method from the voltage and the current of the storage cell at the second time. Further, the differential value between the first remaining energy and the remaining energy of the storage cell at the second time which is calculated by the voltage estimate method from the voltage and the current of the storage cell at the second time, is calculated as the first differential remaining energy.

The second differential remaining energy computation step includes receiving the input of the current acquired from the storage cell at the mentioned time period, and calculating, as the second differential remaining energy, the remaining energy of the storage cell by the current integration method, on the basis of the integrated amount of current during the period for the most recent one cycle (S102).

More specifically, at the second differential remaining energy computation step, the differential value between the remaining energy of the storage cell at the first time and the remaining energy of the storage cell at the second time is calculated, as the second differential remaining energy, by the current integration method on the basis of the integrated amount of current during the period between the first time and the second time.

The storage cell remaining energy computation step includes receiving the input of the current acquired from the storage cell at the mentioned time period, calculating the current range indicating the increase or decrease current during the period for the most recent one cycle, and selecting one of the first differential remaining energy or the second differential remaining energy as the differential remaining energy of the corresponding cycle, depending on the current range. This step further includes adding the differential remaining energy of the corresponding cycle to the remaining energy of the storage cell in the preceding cycle, to thereby output the latest remaining energy of the storage cell (S103). Here, the latest remaining energy of the storage cell indicates the remaining energy of the storage cell at the next period for the remaining energy of the storage cell at the preceding cycle.

More specifically, at the storage cell remaining energy computation step, the current range indicating the increase or decrease of the current is calculated, on the basis of the current of the first time and the current of the second time. Further, one of the first differential remaining energy or the second differential remaining energy is selected as the differential remaining energy, depending on the current range. Then the sum of the first remaining energy and the selected differential remaining energy is outputted as the remaining energy of the storage cell at the second time.

Since the respective processes performed at steps S101 and S102 are not correlated, the sequence of those steps is not limited.

A computer-readable recording medium containing a program according to the first embodiment, will now be described hereunder.

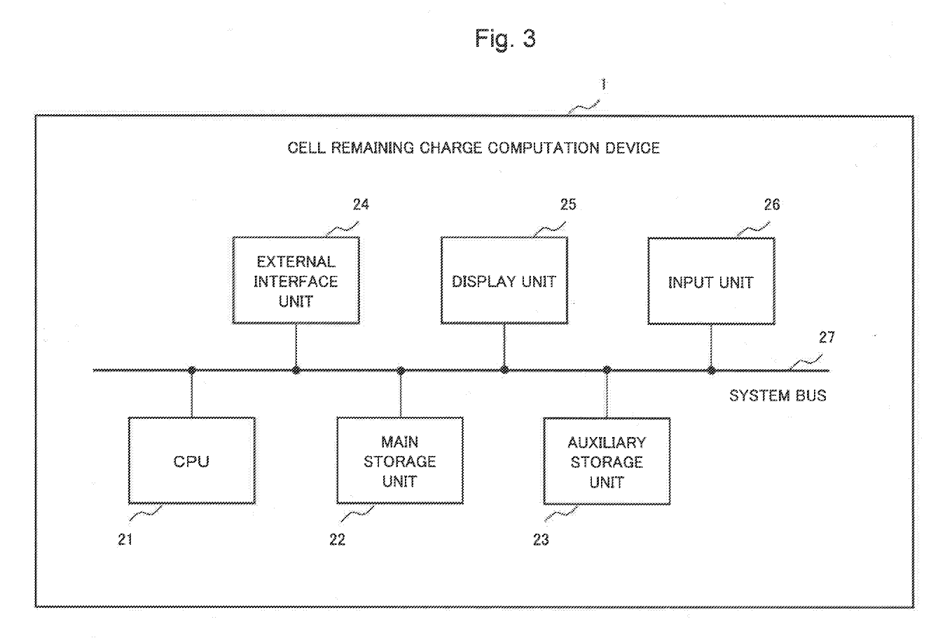

FIG. 3 is a block diagram showing an example of hardware configuration of the cell remaining energy computation device of the first embodiment of the present invention.

Referring to FIG. 3, the cell remaining energy computation device 1 can be achieved with the hardware components similar to that of a popular computer device and includes the following configuration.

The hardware components include a CPU (central processing unit) 21 serving as a control unit, a main storage unit 22, and an auxiliary storage unit 23. The main storage unit 22 includes a RAM (random access memory) and the like, and the auxiliary storage unit 23 includes a hard disk unit constituted of a non-volatile memory such as a magnetic disk, a semiconductor memory.

The hardware components further include an external interface unit 24 for acquiring information from outside, a display unit 25 constituted by a display device, an input unit 26 having keys to be operated, and a system bus 27 and the like connecting the mentioned components to each other.

The operation of the cell remaining energy computation device 1 according to the present embodiment may be achieved by mounting therein, circuit parts including hardware components such as an LSI (large scale integration), in which a program for realizing the respective functions of the cell remaining energy computation device 1 is installed. Such a program may be distributed in the form of a general-purpose semiconductor recording device such as a CF (Compact Flash, registered trademark) and an SD (secure digital), a magnetic recording medium such as a flexible disk, or an optical recording medium such as a CD-ROM (compact disk read-only memory). The functions of the cell remaining energy computation device 1 in this embodiment may be achieved in a form of software, by reading the cell remaining energy computation program from the recording medium and executing the program with the CPU 21 of the computer processing device. Alternatively, the cell remaining energy computation device 1 in this embodiment may be achieved in a form of software, by executing a program that provides each functions of the mentioned respective components with the CPU 21 of the computer processing device.

Thus, the CPU 21 achieves the respective functions in a form of software, by loading a program stored in the auxiliary storage unit 23 on the main storage unit 22 and executing the program, or directly executing the program on the auxiliary storage unit 23, to control the operation of the cell remaining energy computation device 1.

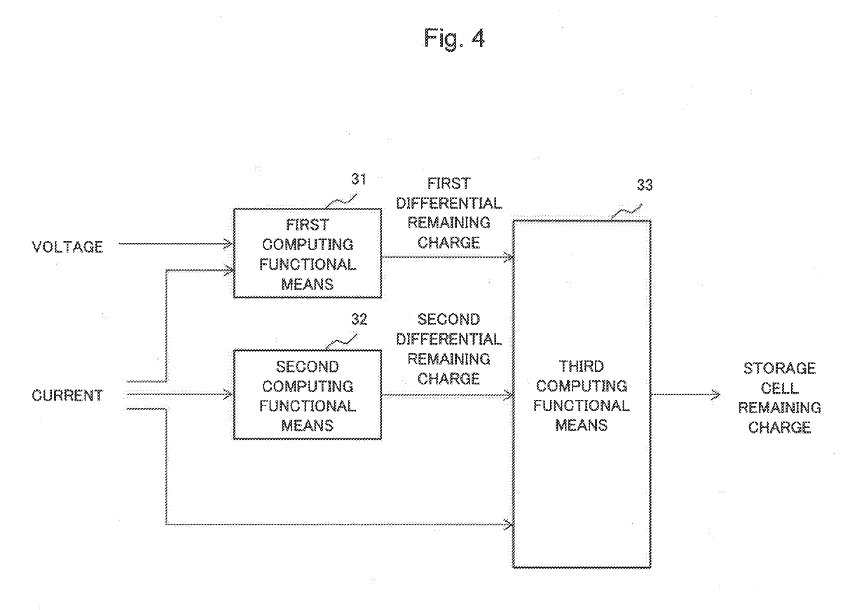

FIG. 4 illustrates a configuration of functional means achieved by the computer-readable recording medium containing the program according to the first embodiment of the present invention.

The program stored in the recording medium in this embodiment causes a computer to act as first computing functional means 31, second computing functional means 32, and third computing functional means 33.

The first computing functional means 31 receives the input of the voltage and the current which are acquired from the storage cell at the prescribed time period, and calculates the remaining energy of the storage cell as the first remaining energy by the voltage estimate method. The first computing functional means 31 then calculates, as the first differential remaining energy, a differential value with respect to the first remaining energy calculated by the voltage estimate method based on the voltage and the current which are acquired during the preceding cycle.

More specifically, the first computing functional means 31, for example, calculates the first remaining energy from the voltage and the current of the storage cell which are acquired at the first time by the voltage estimate method, the first remaining energy indicating the remaining energy of the storage cell at the first time. Then the first computing functional means 31 calculates the remaining energy of the storage cell at the second time, by the voltage estimate method from the voltage and the current of the storage cell acquired at the second time. Further, the first computing functional means 31 calculates, as the first differential remaining energy, the differential value between the first remaining energy and the remaining energy of the storage cell at the second time which is calculated by the voltage estimate method from the voltage and the current acquired from the storage cell at the second time.

The second computing functional means 32 receives the input of the current acquired from the storage cell at the mentioned time period, and calculates the remaining energy of the storage cell by the current integration method as the second differential remaining energy, on the basis of the integrated amount of current during the period for the most recent one cycle.

More specifically, the second computing functional means 32 calculates, as the second differential remaining energy, the differential value between the remaining energy of the storage cell at the first time and the remaining energy of the storage cell at the second time by the current integration method, on the basis of the integrated amount of current during the period between the first time and the second time.

The third computing functional means 33 receives an input of the current acquired from the storage cell at the mentioned time period, calculates the current range representing the increase or decrease of the current during the period for the most recent one cycle, and selects one of the first differential remaining energy or the second differential remaining energy as the differential remaining energy of the corresponding cycle, depending on the current range. Then the third computing functional means 33 adds the differential remaining energy of the corresponding cycle to the remaining energy of the storage cell at the preceding cycle, thereby outputting the added charges as the latest remaining energy of the storage cell. Here, the latest remaining energy of the storage cell indicates the remaining energy of the storage cell at the next period for the remaining energy of the storage cell at the preceding cycle.

More specifically, the third computing functional means 33 calculates the current range indicating the increase or decrease of the current, on the basis of the current of the first time and the current of the second time. Further, the third computing functional means 33 selects one of the first differential remaining energy or the second differential remaining energy as the differential remaining energy, depending on the current range. Then the third computing functional means 33 outputs the sum of the first remaining energy and the selected differential remaining energy, as the remaining energy of the storage cell at the second time.

As described above, in this embodiment, one of the first differential remaining energy calculated by the voltage estimate method on the basis of the current range and the second differential remaining energy calculated by the current integration method is selected, and the selected remaining energy is utilized as the differential remaining energy of the corresponding cycle. Accordingly, when the current range is large, the second differential remaining energy calculated by the current integration method is selected, instead of selecting the first differential remaining energy calculated by the voltage estimate method which may reduce the calculation accuracy of the remaining energy. In contrast, when the current range is stable in a small range, the first differential remaining energy calculated by the voltage estimate method is selected, because of high calculation accuracy of the remaining energy. Further, even when the current integration method is selected for calculating the remaining energy, the differential remaining energy is calculated exclusively on the basis of the integrated amount of current during the period for the most recent cycle. Hence calculation based on the voltage estimate method can prevent deteriorated of calculation accuracy of the remaining energy. In other words, the integration error, a major defect of the current integration method, is limited only to period for the most recent one cycle integration error, divided for each prescribed time periods.

Therefore, this embodiment can measure the remaining energy with high accuracy, despite combining the calculation method of the remaining energy of the storage cell based on the voltage with the calculation method of the remaining energy of the storage cell based on the current integration.

### Second Embodiment

A second embodiment will be described hereunder.

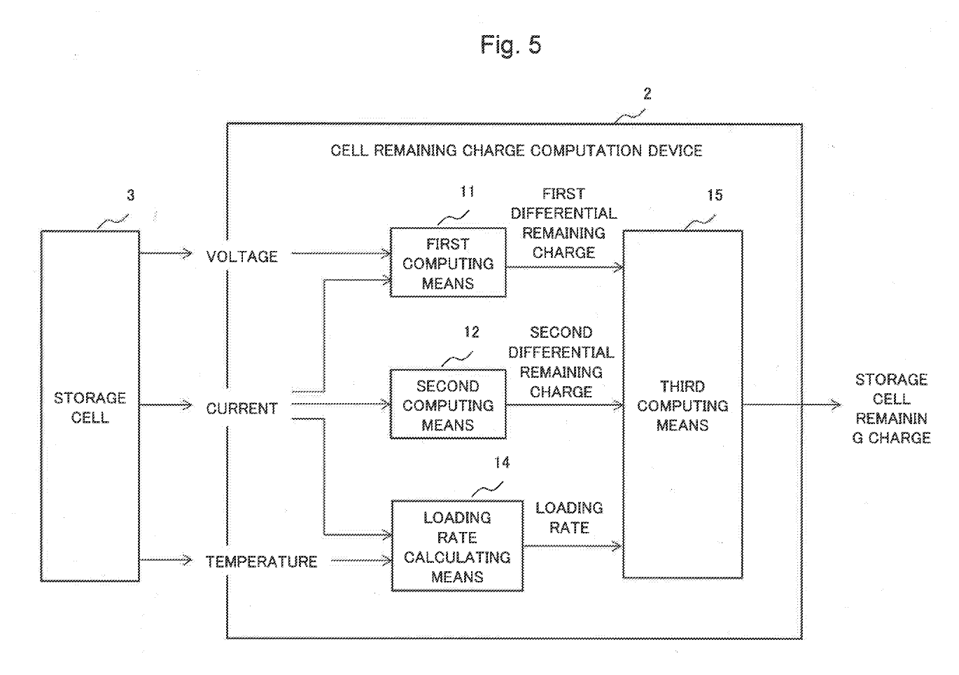

FIG. 5 is a block diagram showing a configuration of a cell remaining energy computation device according to the second embodiment of the present invention.

The cell remaining energy computation device 2 according to the second embodiment is different from the cell remaining energy computation device 1 of the first embodiment, in further including loading rate calculating means 14. In addition, the function of third computing means 15 is different from that of the third computing means 13 of the first embodiment.

The differences from the first embodiment will be described hereunder.

The loading rate calculating means 14 receives an input of the current and temperature which are acquired from the storage cell 3 at a prescribed time period, and calculates the current range indicating the increase or decrease of the current during the period for the most recent one cycle. More specifically, the loading rate calculating means 14 receives the input of the current and temperature acquired from the storage cell 3 at the prescribed time period, and calculates the current range representing the increase or decrease of the current, for example from the current at the first time and the current at the second time. Then the loading rate calculating means 14 calculates the loading rate indicating the use ratio of the second differential remaining energy, on the basis of the prescribed correlation between the current range calculated as above and the temperature.

The third computing means 15 calculates a third differential remaining energy, as the remaining energy of the corresponding cycle, by distributing weight to the first differential remaining energy and the second differential remaining energy according to the loading rate. Then the third computing means 15 adds the third differential remaining energy to the remaining energy of the storage cell 3 at the preceding cycle, and outputs the added remaining energy as the latest remaining energy of the storage cell 3.

More specifically, the third computing means 15 outputs the sum of the first remaining energy calculated by the voltage estimate method from the voltage and the current of the storage cell 3 at the first time and the third differential remaining energy, as the remaining energy of the storage cell 3 at the second time.

Here, the expression “distributing weight to the first differential remaining energy and the second differential remaining energy according to the loading rate” means adding the second differential remaining energy and a ratio of the first differential remaining energy on the assumption that the maximum value of the loading rate is defined as 1, the second differential remaining energy being corresponding to the load rate, and the ratio being obtained by subtracting the loading rate from 1. This also applies to the subsequent descriptions.

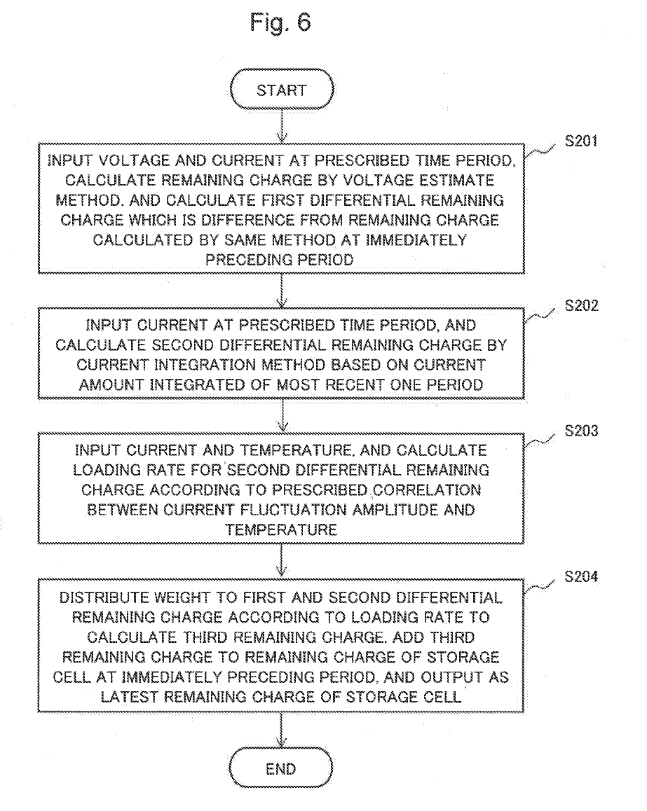

FIG. 6 is a flowchart showing steps of processing of a cell remaining energy computation method according to the second embodiment of the present invention.

The cell remaining energy computation method of the second embodiment is different from the cell remaining energy computation method of the first embodiment in further including a loading rate computation step (S203). In addition, the process performed at the storage cell remaining energy computation step differs from that of the first embodiment. Processing in steps S201 and S202 are the same as the processing in steps S101 and S102 of the first embodiment.

The differences from the first embodiment will be described hereunder.

The loading rate computation step includes receiving the input of the current and the temperature acquired from the storage cell at the prescribed time period, calculating the current range representing the increase or decrease of the current during the period for the most recent one cycle, and calculating the loading rate indicating the use ratio of the second differential remaining energy, according to the prescribed correlation between the current range and the temperature (S203).

More specifically, the loading rate computation step includes receiving the input of the current and the temperature which are acquired from the storage cell at the prescribed time period, and calculating the current range representing the increase or decrease of the current, for example from the current at the first time and the current at the second time. Then the loading rate indicating the use ratio of the second differential remaining energy is calculated, according to the prescribed correlation between the current range and the temperature.

The storage cell remaining energy computation step includes calculating the third differential remaining energy, which is the remaining energy of the corresponding cycle, by distributing weight to the first differential remaining energy and the second differential remaining energy according to the loading rate. This step also includes adding the third differential remaining energy to the remaining energy of the storage cell at the preceding cycle, and outputting the added remaining energy as the latest remaining energy of the storage cell (S204). Here, the latest remaining energy of the storage cell indicates the remaining energy of the storage cell at the next period for the remaining energy of the storage cell at the preceding cycle.

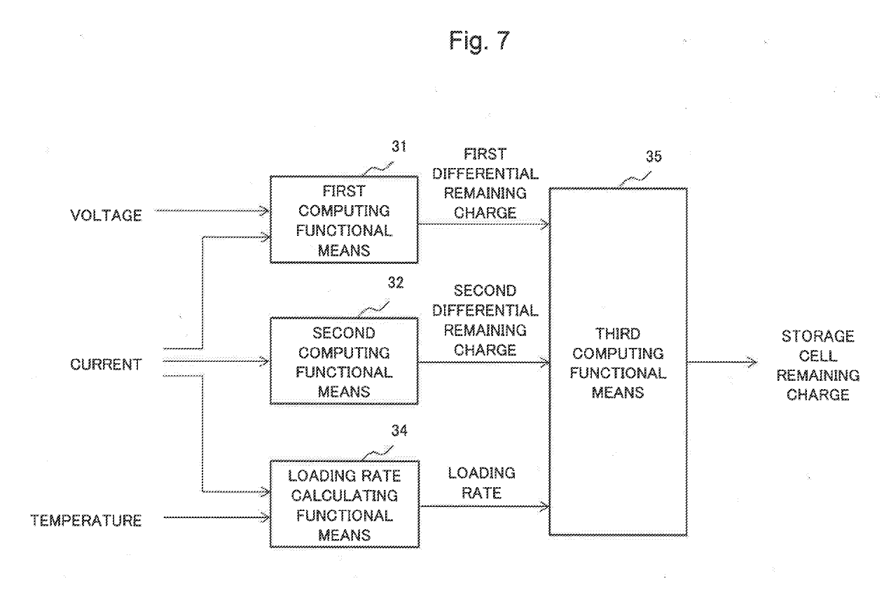

FIG. 7 is a block diagram showing a configuration of the functional means achieved by the computer-readable recording medium containing the program according to the second embodiment of the present invention.

The cell remaining energy computation program of the second embodiment is different from the cell remaining energy computation program of the first embodiment in further including loading rate calculating functional means 34. In addition, the function of third computing functional means 35 differs from that of the third computing functional means 33 of the first embodiment.

The differences from the first embodiment will be described hereunder.

The loading rate calculating functional means 34 receives the input of the current and temperature acquired from the storage cell at a prescribed time period, and calculates the current range representing the increase or decrease of the current during the period for the most recent one cycle. More specifically, the loading rate calculating functional means 34 receives the input of the current and temperature acquired from the storage cell at the prescribed time period, and calculates the current range representing the increase or decrease of the current, for example from the current at the first time and the current at the second time. Then the loading rate calculating functional means 34 calculates the loading rate indicating the use ratio of the second differential remaining energy, on the basis of the prescribed correlation between the current range and the temperature.

The third computing functional means 35 calculates the third differential remaining energy, which is the remaining energy of the corresponding cycle, by distributing weight to the first differential remaining energy and the second differential remaining energy according to the loading rate. Then the third computing functional means 35 adds the third differential remaining energy to the remaining energy of the storage cell at the preceding cycle, and outputs the added remaining energy as the latest remaining energy of the storage cell.

More specifically, the computing functional means 35 outputs the sum of the first remaining energy calculated by the voltage estimate method from the voltage and the current of the storage cell at the first time and the third differential remaining energy, as the remaining energy of the storage cell at the second time.

As described above, in this embodiment, the third differential remaining energy which is the differential remaining energy of the corresponding cycle, is calculated by optimally distributing weight to the first differential remaining energy and the second differential remaining energy according to the loading rate. In other words, in this embodiment, the loading rate is calculated based on the prescribed correlation between the temperature and the current range of period for the most recent one cycle and the temperature, the loading rate indicating the use ratio of the second differential remaining energy calculated by the current integration method. Such an arrangement is intended to employ the voltage estimate method whenever possible when the current range is small, in order to calculate the remaining energy of the storage cell with high accuracy. When the current range is large, the ratio of the remaining energy of the storage cell calculated by the current integration method is increased for compensating the deteriorated in accuracy of the calculation of the remaining energy of the storage cell by the voltage estimate method.

Further, even when the remaining energy of the storage cell is calculated by the current integration method is selected for calculating the remaining energy of the storage cell, the remaining energy is calculated, as in the first embodiment, based only on the integrated amount of current during the period for the most recent one cycle. Hence calculation by the current integration method can prevent the deteriorated of the calculation accuracy of the remaining energy.

Therefore, this embodiment can measure the remaining energy, despite combining the calculation method of the remaining energy of the storage cell based on the voltage and the calculation method of the remaining energy of the storage cell based on the current integration.

### Third Embodiment

A third embodiment will be described hereunder.

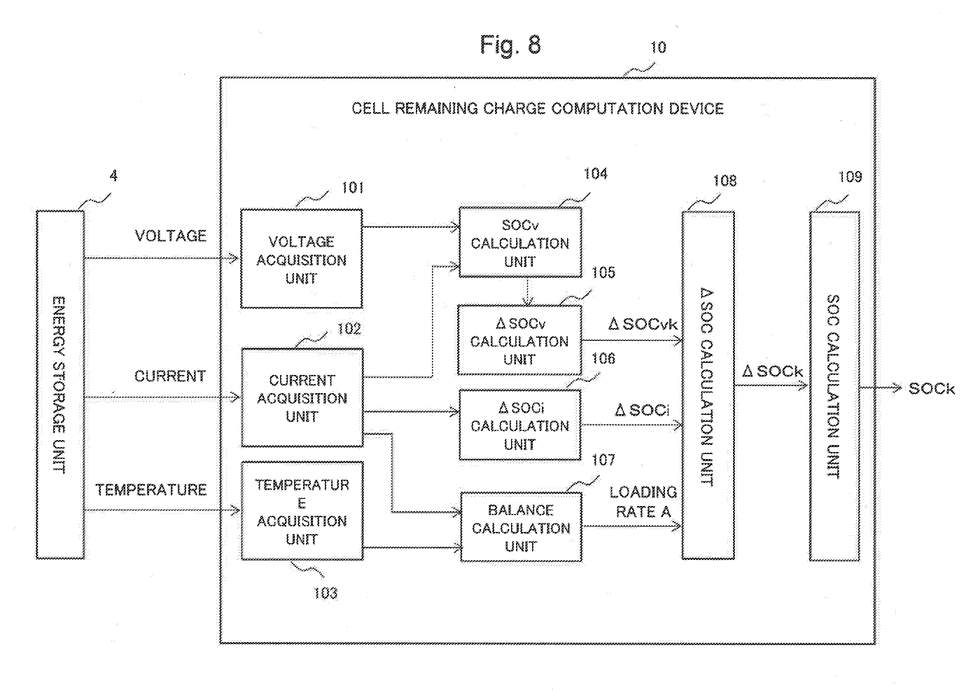

FIG. 8 is a block diagram showing a configuration of a cell remaining energy computation device according to the third embodiment of the present invention.

The third embodiment provides further details of the second embodiment.

A cell remaining energy computation device 10 according to the third embodiment acquires status information of the energy storage unit 4 (voltage, current, temperature) at a prescribed time period (e.g., one second period), and calculates and outputs the SOC of the energy storage unit 4, which is the remaining energy represented by a ratio of charged electricity amount to the electric capacity of the energy storage unit 4.

The energy storage unit 4 may be an energy storage device of various types, including various secondary batteries such as a lithium ion battery, a lead acid battery, a nickel metal hydride battery, or the electric double-layer capacitors. The energy storage unit 4 may include a single energy storage device, or a plurality of energy storage devices connected in series or in parallel.

The cell remaining energy computation device 10 includes a voltage acquisition unit 101, a current acquisition unit 102, and a temperature acquisition unit 103, as a configuration to acquire the status information of the energy storage unit 4.

The cell remaining energy computation device 10 includes a SOCv calculation unit 104, a ΔSOCv calculation unit 105, a ΔSOCi calculation unit 106, a balance calculation unit 107, a ΔSOC calculation unit 108, and an SOC calculation unit 109, as a configuration to calculate the SOC.

The voltage acquisition unit 101, for example, measures a cell voltage or total voltage of the energy storage unit 4, with a voltage measurement device such as a cell monitoring IC (integrated circuit).

The current acquisition unit 102 measures a discharge current in a discharging phase and a charging current in a charging phase of the energy storage unit 4, with a current measurement device such as a hall element or a shunt resistor. The current acquisition unit 102 may include a low-pass filter for noise removal.

The temperature acquisition unit 103 measures a temperature of the energy storage unit 4 with a temperature measurement device such as a thermistor or a thermocouple.

The SOCv calculation unit 104 is, for example, constituted of a microcomputer or the like. The SOCv calculation unit 104 estimates the open circuit voltage from a voltage (terminal voltage) measured by the voltage acquisition unit 101 at the time k and a current measured by the current acquisition unit 102 at the time k, and calculates SOCvk on the basis of the estimated open circuit voltage. The SOCvk represents the SOC calculated by the voltage estimate method from the voltage and the current measured at the time k. Alternatively, as described above, the method of estimating the open circuit voltage includes the method of estimating the open circuit voltage by adding or subtracting the internal resistance calculated from the terminal voltage and the current to a voltage drop at the current flowing, to and the method of estimating the open circuit voltage by utilizing an equivalent circuit model of the cell or an adaptive digital filter.

Thus, the SOCv calculation unit 104 calculates the SOCvk of the energy storage unit 4 by the voltage estimate method, on the basis of the voltage and the current of the energy storage unit 4 which are acquired at the prescribed time period (e.g., one second period). In the description given hereafter, the preceding cycle of the time k is expressed as time k−1, and the next period of the time k is expressed as time k+1. The SOC of the energy storage unit 4 calculated by the voltage estimate method from the voltage and the current of the energy storage unit 4 which are acquired at the time k−1 is expressed as SOCvk−1. Likewise, the SOC of the energy storage unit 4 calculated by the voltage estimate method from the voltage and the current of the energy storage unit 4 which are acquired at the time k+1 is expressed as SOCvk+1.

The ΔSOCv calculation unit 105 is, for example, constituted of a microcomputer or the like. The ΔSOCv calculation unit 105 calculates ΔSOCvk, which is the differential value between SOCvk and SOCvk−1.

The SOCvk−1 calculated by the SOCv calculation unit 104 from the voltage and the current of the energy storage unit 4 acquired at the time k−1 may be stored in the SOCv calculation unit 104 or in the ΔSOCv calculation unit 105.

Here, the SOCv calculation unit 104 and the ΔSOCv calculation unit 105 correspond to the first computing means 11 of the second embodiment, and the ΔSOCvk corresponds to the first differential remaining energy.

The ΔSOCi calculation unit 106 is, for example, constituted of a microcomputer or the like, and calculates ΔSOCi by the current integration method from the current measured by the current acquisition unit 102, on the basis of the integrated amount of current during one time period. More specifically, the ΔSOCi calculation unit 106 calculates the ΔSOCi, for example on the basis of the integrated amount of current during the period between the time k−1 and the time k. Accordingly, the ΔSOCi may be calculated through the following equation.

ΔSOCi={(integrated amount of current between time k and time k−1) of preceding cycle/full charge energy}×100

Thus, in this embodiment, the ΔSOCi is calculated on the basis of the integrated amount of current flowing during the period of the most recent one-period.

Here, the ΔSOCi calculation unit 106 corresponds to the second computing means 12 of the second embodiment, and the ΔSOCi corresponds to the second differential remaining energy.

The balance calculation unit 107 is, for example, constituted of a microcomputer or the like, receives an input of the current acquired by the current acquisition unit 102 and the temperature of the energy storage unit 4 acquired by the temperature acquisition unit 103, and calculates a loading rate A to be applied to the ΔSOCi. As will be subsequently described the loading rate A is a value utilized for the purpose of weighting the use ratio of the ΔSOCi.

The balance calculation unit 107 calculates the current range from the current of one second ago and the current of the corresponding second, one second ago corresponding the period for the most recent one cycle. Then the balance calculation unit 107 acquires the loading rate A according to the prescribed correlation between the current range and the temperature.

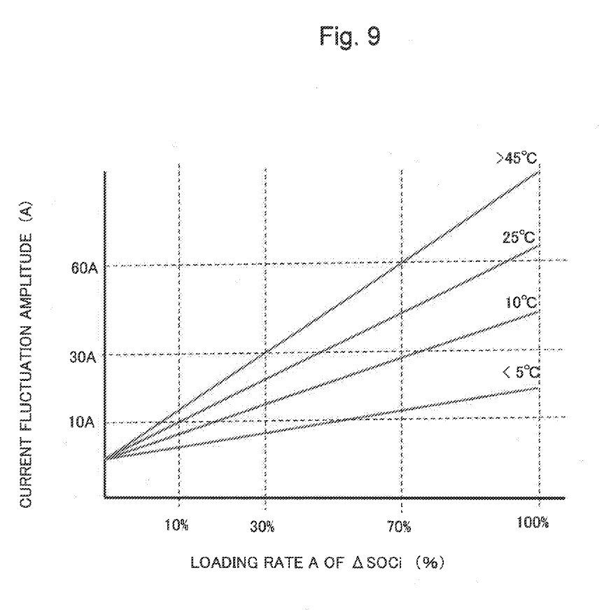

FIG. 9 is a graph showing a prescribed correlation between the current range and the temperature, for obtaining a loading rate A of ΔSOCi. The loading rate A is obtain according to the prescribed correlation between the current range and the temperature as exhibited in FIG. 9. The loading rate A becomes higher, the lower the temperature is and the larger the current range is.

The balance calculation unit 107 contains a graph or a map which can obtain the loading rate A from the prescribed correlation between the current range and the temperature.

By inputting the current range and the temperature to the balance calculation unit 107, the loading rate A can be obtained by referring to the graph or the map. Alternatively, the balance calculation unit 107 may contain, in place of the graph or the map, a function calculating means corresponding to the graph or the map.

Here, the balance calculation unit 107 corresponds to the loading rate computing means 14 of the second embodiment.

The ΔSOC calculation unit 108 calculates ΔSOCk by distributing the weight to the ΔSOCvk calculated by the ΔSOCv calculation unit 105 and the ΔSOCi calculated by the ΔSOCi calculation unit 106 by the loading rate A of the ΔSOCi calculated, by the balance calculation unit 107 as the equation cited below. Here, the ΔSOCk is the differential remaining energy of the corresponding cycle, and corresponds to the third differential remaining energy of the second embodiment.

ΔSOCₖ=(ΔSOCi×A)+{ΔSOCvk×(1−A)}

As mentioned above, the loading rate A becomes higher, the lower the temperature is or the larger the current range is, and hence the use ratio of the ΔSOCi calculated by the current integration method becomes higher, the larger the current range is. Referring to FIG. 9, for example when the temperature of the energy storage unit 4 is 5° C. or lower, and when the current range is approximately 20 A, the ΔSOCi calculated by the current integration method is used as the ΔSOCk with the ratio of 100%. In contrast, when the current range is approximately 5 A or smaller, the loading rate of 0% is applied, and therefore the ΔSOCvk calculated by the voltage estimate method is used as the ΔSOCk, instead of the ΔSOCi calculated by the current integration method.

The SOC calculation unit 109 adds the ΔSOCk of the corresponding cycle calculated by the ΔSOC calculation unit 108, to the SOCk−1 which is the remaining energy of the energy storage unit 4 outputted at the preceding cycle (one second ago), and outputs the obtained value as the SOCk representing the remaining energy of the energy storage unit 4 at the latest time. In other words, the sum of the SOCk−1 and the ΔSOCk is outputted as the remaining energy SOCk of the energy storage unit 4 at the time k. Thus, the SOC calculation unit 109 uses the following equation to calculate and output the SOCk.

SOCk=(SOCk−1)+(ΔSOCk)

Then the SOC calculation unit 109 stores the SOCk calculated at the latest time, to utilize the SOCk for the calculation of the SOCk+1 of the next time.

Here, the ΔSOC calculation unit 108 and the SOC calculation unit 109 correspond to the third computing means 15 of the second embodiment.

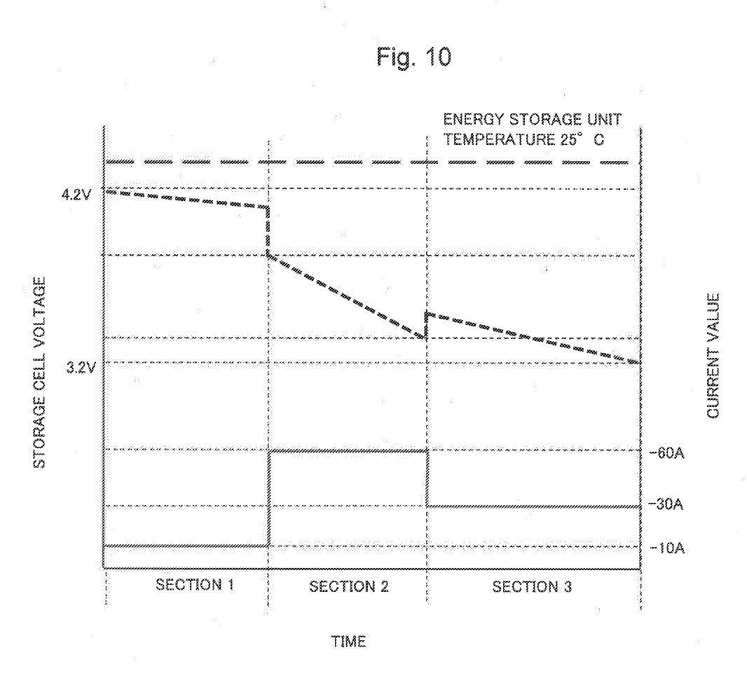

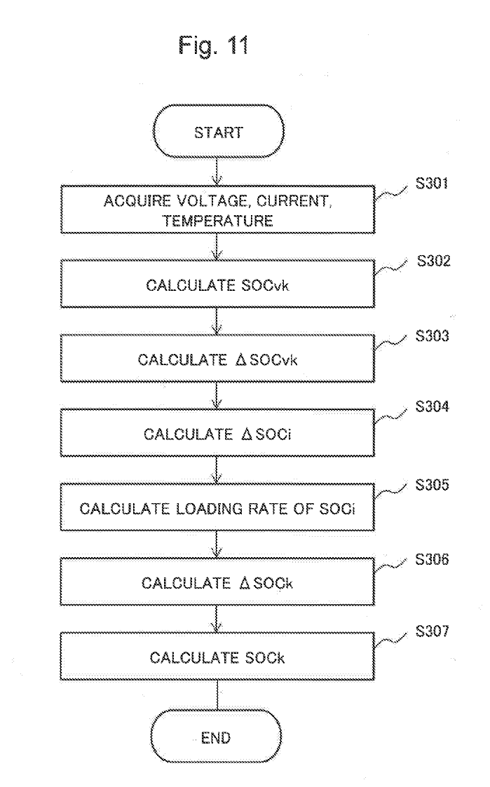

A cell remaining energy computation method performed by the operation of the cell remaining energy computation device 10 configured as above according to the third embodiment will be described with reference to FIG. 10 and FIG. 11.

FIG. 10 is a diagram showing an example of discharge pattern in the remaining energy measurement.

For the measurement of the cell remaining energy in this embodiment, an external environment assumes that the temperature of the energy storage unit is at 25° C. as indicated by broken lines in the uppermost region of FIG. 10, and that the current changes in a pattern indicated by solid lines in the lowermost region of FIG. 10.

In a first section 1, the discharge was performed with a constant current of −10 A, in a next section 2, the discharge was performed with a constant current of −60 A, and in the last a section 3, the discharge was performed with a constant current of −30 A. Although not shown, a charging current is indicated with a plus code (+).

The fluctuation of the terminal voltage of the energy storage unit 4 originating from the illustrated discharge pattern is indicated by dotted lines in the middle region of FIG. 10.

FIG. 11 is a flowchart showing steps of processing of the cell remaining energy computation method in this embodiment. The steps are repeated at a prescribed period.

First, the voltage, the current, and the temperature of the energy storage unit 4 are acquired by the voltage acquisition unit 101, the current acquisition unit 102, and the temperature acquisition unit 103, at intervals of one second (S301).

The operations according to steps S302, S303, S304, and S305 are performed on the basis of the voltage, the current, and the temperature acquired as above. Since the operation of steps S302 and S303, the operation of step S304, and the operation of step S305 are not correlated, the sequence of those steps is not specifically limited.

At step S302, the SOCv calculation unit 104 estimates the open circuit voltage by the voltage estimate method from the voltage acquired at the time k and the current acquired at the time k, and calculates the SOCvk at the time k from the estimated open circuit voltage. At step S303, the ΔSOCv calculation unit 105 calculates the ΔSOCvk, representing the differential value between the SOCvk at the time k and the SOCvk−1 at the time k−1, which is the preceding cycle of the time k.

At step S304, the ΔSOCi calculation unit 106 calculates the ΔSOCi by the current integration method, on the basis of the integrated amount of current during the most recent one-period (one second). More specifically, the ΔSOCi calculation unit 106 calculates the ΔSOCi on the basis of the integrated amount of current during the period between the time k−1 and the time k.

At step S305, the balance calculation unit 107 calculates the current range from the difference between the current at the latest time and the current at the preceding cycle, and calculates the loading rate A of the ΔSOCi, from the current range and the temperature of the energy storage unit 4. More specifically, the balance calculation unit 107 calculates the current range indicating the increase or decrease of the current, from the difference between the current at the time k−1 and the current at the time k, and calculates the loading rate A of the ΔSOCi from the current range and the temperature of the energy storage unit 4.

After the ΔSOCvk, the ΔSOCi, and the loading rate A are calculated, the ΔSOC calculation unit 108 distributes the weight to the ΔSOCvk and the ΔSOCi by the loading rate A, to thereby calculate the ΔSOCk, representing the differential remaining energy of the corresponding cycle (S306).

After the ΔSOCk is calculated, the SOC calculation unit 109 adds the ΔSOCk to the SOCk−1 representing the remaining energy of the energy storage unit 4 at the time k−1, and outputs the sum as SOCk representing the remaining energy of the energy storage unit 4 at the time k (S307).

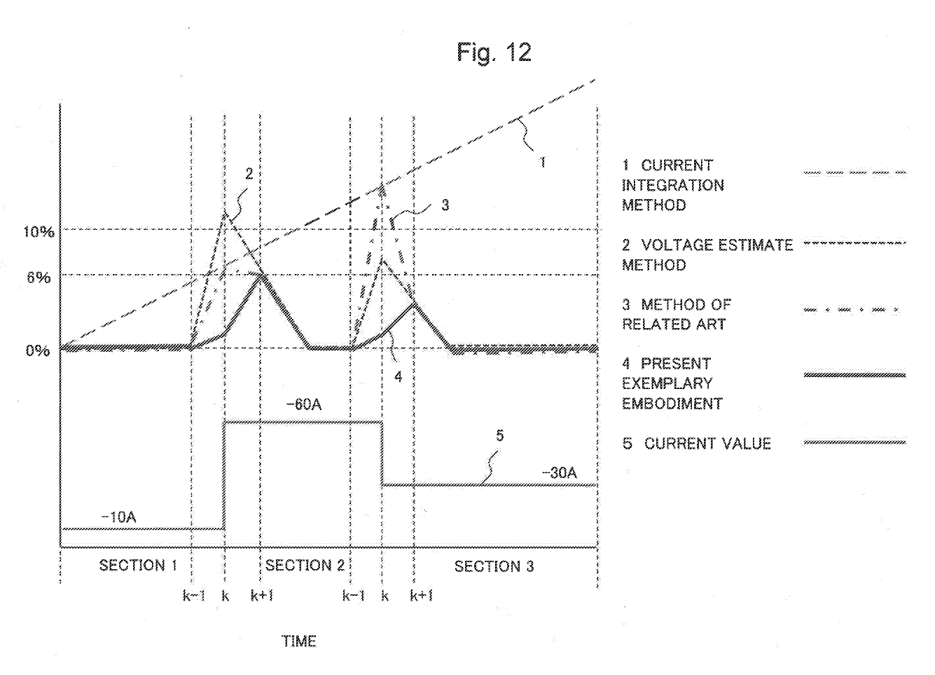

Referring to FIG. 12, the advantageous effects of the cell remaining energy computation in this embodiment will be described hereunder.

FIG. 12 is a diagram showing differences of the error relative to a SOC true value between the cell remaining energy computation by the current integration method, the voltage estimate method, and the method according to the related art, and the cell remaining energy computation in the third embodiment of the present invention.

In FIG. 12, the horizontal axis represents the lapse of time, and the vertical axis represents the ratio of the error for the true value of the SOC. Here, the true value of the SOC refers to a simulated value obtained by integrating ideal currents free from offset or noise.

In FIG. 12, broken lines denoted by a numeral 1 represent the change of the error in the calculation based on the current integration method, dotted lines denoted by a numeral 2 represent the change of the error in the calculation based on the voltage estimate method, and dash-dot lines denoted by a numeral 3 represent the change of the error in the calculation based on the method of the related art. The solid line by a numeral 4 indicates the change of the error in the calculation by the method in this embodiment.

The current fluctuation pattern used for the evaluation is indicated by solid lines denoted by a numeral 5 in the lowermost region of FIG. 12.

The method according to the related art is, as disclosed in Patent Literature 1, assumed to be the method in which the SOC calculated by the voltage estimate method is switched to the SOC calculated by the current integration method when current fluctuation is imposed on the battery. In other words, the SOC calculated by the voltage estimate method is utilized up to the time k when the occurrence of the abrupt current fluctuation can be detected, and at the time k, the SOC is switched to the SOC calculated by the current integration method. Then at the time k+1 when the current is decided to have been stabilized, the SOC is again switched to the SOC calculated by the voltage estimate method.

When only the current integration method is employed (broken lines of numeral 1), the integration error in the current integration is accumulated so as to increase, according to the lapse of time.

When only the voltage estimate method is employed (dotted lines of numeral 2), the accuracy is deteriorated at the time point (time k) when the abrupt change of the current occurs. The accuracy is deteriorated at the time k between the section 1 and the section 2 and at the time k between the section 2 and the section 3. In the former case, the deteriorated in accuracy originates from the current range of 50 A, and in the latter case, the deteriorated in accuracy originates from the current range of 30 A.

In the case of the method according to the related art (dash-dot lines of numeral 3), the SOC is switched to the SOC calculated by the current integration method at the time point when the abrupt change of the current occurs (time k). However the SOC contains the integration error accumulated up to the time k. The SOC based on the current integration method selected at the time k between the section 2 and the section 3 contains a further increased integration error, because this time point is further ahead in time from the time k between the section 1 and the section 2.

In contrast, when the method in this embodiment (solid lines of numeral 4) is employed, the SOC is switched to the SOC calculated by the current integration method at the time point when the abrupt change of the current occurs (time k). However, the SOC calculated at this time point only contains the integration error due to the current integration for the most recent one cycle (one second from time k−1 to time k).

Accordingly, the error is suppressed to a low level despite switching to the current integration method. In addition, the SOC is again switched to the SOC calculated by the voltage estimate method at the time point when the current has been stabilized (time k+1).

Here, in the case where the SOC is switched to the SOC by the voltage estimate method at the time k+1, the deteriorated in accuracy at the time k when the abrupt change of the current occurs has not yet been completely converged, and therefore the accuracy continues to be deteriorated during a prescribed converging time. This issue will be subsequently described in a fourth embodiment.

Thus, in this embodiment, the weight is distributed to the ΔSOCvk calculated by the voltage estimate method and the ΔSOCi calculated by the current integration method according to the loading rate A, to thereby calculate the ΔSOCk of the corresponding cycle. Then the ΔSOCk is added to the SOCk−1 representing the remaining energy of the energy storage unit 4 outputted at the preceding cycle, to thereby calculate the SOCk of the energy storage unit 4 at the latest time point. In other words, the sum of the SOCk−1 and the ΔSOCk is outputted as the remaining energy SOCk of the energy storage unit 4 at the time k.

The loading rate A indicating the use ratio of the ΔSOCi calculated by the current integration method is calculated based on the prescribed correlation between the current range during the period for the most recent one cycle (one second) and the temperature.

The foregoing arrangement is intended to employ the voltage estimate method to calculate the SOC of the energy storage unit 4 with high accuracy, whenever possible when the current range is small. When the current range is large, the ratio of the SOC of the energy storage unit 4 calculated by the current integration method is increased, so as to compensate the deteriorated of the calculation accuracy of the SOC of the energy storage unit 4 based on the voltage estimate method.

Further, even when the current integration method is selected for calculating the SOC of the energy storage unit 4, the SOC is calculated exclusively on the basis of the integrated amount of current during the period for the most recent cycle. Hence the calculation based on the current integration method can prevent deteriorated of calculation SOC of the SOC. In other words, the integration error, a major defect of the current integration method, is limited only to period for the most recent one cycle integration error (for one second), divided for each prescribed time periods.

Therefore, this embodiment can measure the remaining energy with high accuracy, despite combining the calculation method of the remaining energy of the storage cell based on the voltage with the calculation method of the remaining energy of the storage cell based on the current integration.

### Fourth Embodiment

Hereunder, a fourth embodiment will be described.

The fourth embodiment represents a configuration for compensating the drawback of the voltage estimate method that the SOC calculation accuracy is deteriorated due to abrupt current fluctuation and it takes time until the deteriorated is converged, which is not taken into consideration in the third embodiment.

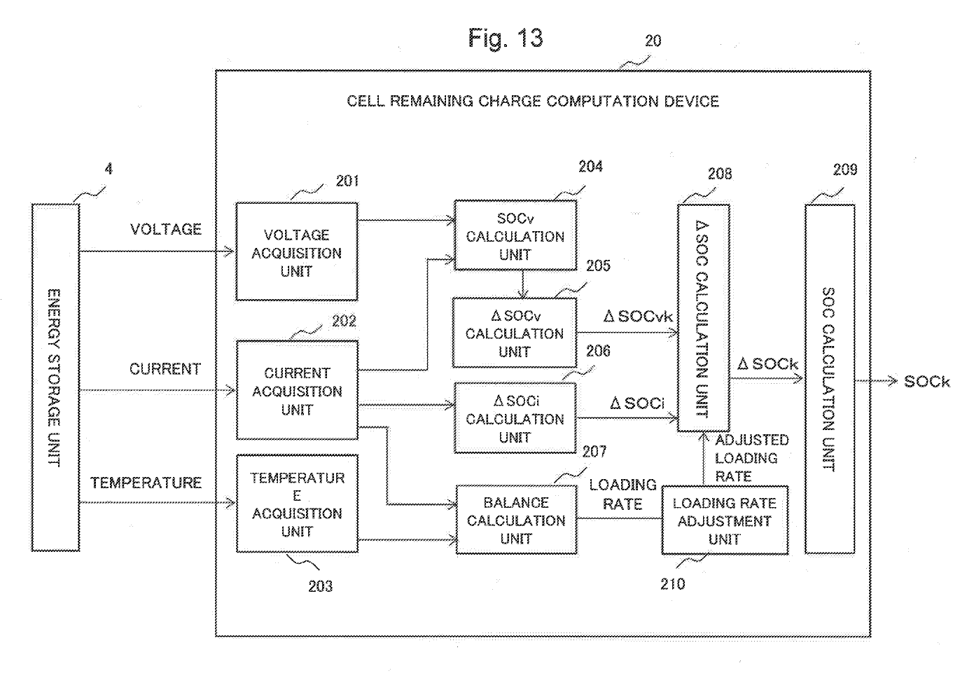

FIG. 13 is a block diagram showing a configuration of a cell remaining energy computation device in a fourth embodiment of the present invention.

A cell remaining energy computation device 20 in the fourth embodiment includes a voltage acquisition unit 201 that acquires the status information of the energy storage unit 4 (voltage, current, temperature) at a prescribed time period (e.g., one second period), a current acquisition unit 202, and a temperature acquisition unit 203. The voltage acquisition unit 201, the current acquisition unit 202, and the temperature acquisition unit 203 have the same components as the respectively corresponding components of the cell remaining energy computation device 10 in the third embodiment shown in FIG. 8, and hence the description will not be repeated.

The cell remaining energy computation device 20 calculates and outputs the SOC, which is the remaining energy represented by a ratio of charged electricity amount to the electric capacity of the energy storage unit 4, on the basis of the acquired status information of the energy storage unit 4.

The cell remaining energy computation device 20 includes, to calculate the SOC, a SOCv calculation unit 204, a ΔSOCv calculation unit 205, a ΔSOCi calculation unit 206, a balance calculation unit 207, a ΔSOC calculation unit 208, and an SOC calculation unit 209, and additionally includes a loading rate adjustment unit 210. The SOCv calculation unit 204, the ΔSOCv calculation unit 20, and the ΔSOCi calculation unit 206 have the same components as the respectively corresponding components of the cell remaining energy computation device 10 in the third embodiment shown in FIG. 8, and hence the description will not be repeated. Likewise, the balance calculation unit 207, the ΔSOC calculation unit 208, and the SOC calculation unit 209 also have the same components as the respectively corresponding components of the cell remaining energy computation device 10 in the third embodiment shown in FIG. 8, and hence the description will not be repeated.

The cell remaining energy computation device 20 in the fourth embodiment is different from the cell remaining energy computation device 10 in the third embodiment, in additionally including the loading rate adjustment unit 210.

The loading rate adjustment unit 210 is, for example, constituted of a microcomputer or the like. The loading rate adjustment unit 210 calculates an adjusted loading rate A′ when the SOC calculated by the voltage estimate method is employed, and outputs the adjusted loading rate A′ to the ΔSOC calculation unit 208, the adjusted loading rate A′ considering a converging time Gt until the deteriorated in accuracy of the SOC due to abrupt current fluctuation is converged.

When the abrupt current fluctuation occurs, the ΔSOCi calculated by the current integration method is employed as described earlier. After the current fluctuation has converged, the ΔSOCvk calculated by the voltage estimate method is employed. However, the ΔSOCi is not immediately switched to the ΔSOCvk calculated by the voltage estimate method when the current fluctuation has converged. When this current fluctuation has converged, converging time Gt controls to take the ΔSOCi calculated by the current integration method into consideration instead immediately switching to the ΔSOCvk calculated by the voltage estimate method, the converging time Gt being converging time until the deteriorated of the SOC accuracy by the abrupt current fluctuation to converge. The loading rate employed in this process corresponds to the adjusted loading rate A′.

The loading rate adjustment unit 210 receives the input of the loading rate outputted from the balance calculation unit 207, to monitor the variation of the loading rate. When the loading rate changes from a first loading rate equal to or higher than a prescribed specified value to a second loading rate equal to or lower than another prescribed specified value, a prescribed time interval is calculated according to the first loading rate. Then the loading rate adjustment unit 210 calculates a subtraction amount of each cycle so that the first loading rate turn to the second loading rate within the prescribed time interval. In other words, the loading rate adjustment unit 210 calculates the subtraction amount of each cycle by dividing the differential value between the first loading rate and the second loading rate by the prescribed time interval. The loading rate adjustment unit 210 then calculates and outputs the adjusted loading rate A′, by sequentially and cumulatively subtracting the subtraction amount from the first loading rate for each cycle.

The prescribed specified value for the decision of the first loading rate is a loading rate calculated from a first current range that is assumed to deteriorate the SOC calculation accuracy based on the voltage estimate method. Another prescribed specified value for the decision of the second loading rate is a loading rate calculated based on a second current range which is assumed to be properly performed the SOC calculation based on the voltage estimate method. The prescribed time interval calculated from the first loading rate is a converging time required for recovery of the SOC calculation accuracy based on the voltage estimate method deteriorated due to the current range used for the calculation of the first loading rate. Here, it will be assumed that the first current range and the second current range are obtained in advance according to past findings, for example based on experiments.

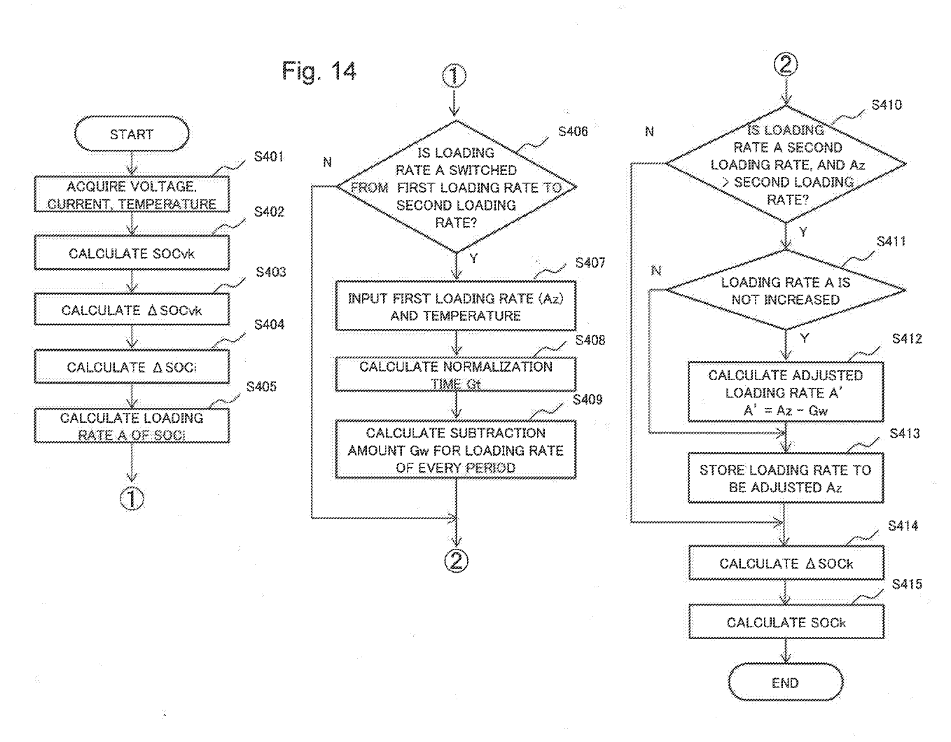

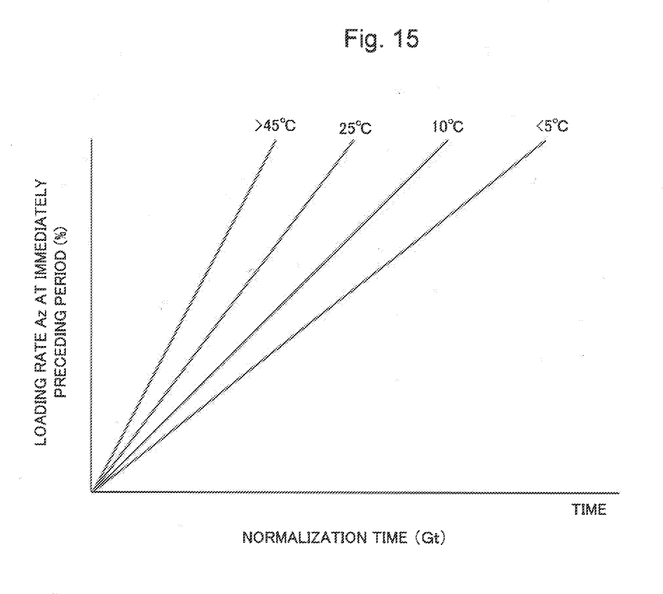

Referring to FIG. 14 and FIG. 15, an operation performed by the loading rate adjustment unit 210 will be described hereunder.

FIG. 14 is a flowchart showing steps of operations of a cell remaining energy computation method according to the fourth embodiment of the present invention.

In FIG. 14, the process from step S401 to step S405 is the same as that of step S301 to step S305 of the cell remaining energy computation method in the third embodiment shown in FIG. 11, and hence the description will not be repeated.

In addition, the process of step S414 and step S415 in FIG. 14 is the same as that of step S306 and step S307 of the cell remaining energy computation method in the third embodiment shown in FIG. 11, and hence the description will not be repeated.

Accordingly, the operation from step S406 to step S413 in FIG. 14 performed by the loading rate adjustment unit 210 will be described hereunder.

The loading rate adjustment unit 210 decides whether it is necessary to calculate the adjusted loading rate A′ (S406) on the basis of the loading rate A calculated and outputted by the balance calculation unit 207 at step S405 and the loading rate Az calculated and stored at the preceding cycle at step S405.

At step S406, it is decided whether the change of the loading rate A through the preceding cycle corresponds to the change from the first loading rate equal to or higher than the prescribed specified value to the second loading rate equal to or lower than another prescribed specified value. In other words, it is decided whether the loading rate Az calculated at the preceding cycle at step S405 corresponds to the first loading rate and whether the loading rate A of the latest time calculated and outputted at step S405 corresponds to the second loading rate.

This monitors the return from the state where the ΔSOCi calculated by the current integration method is employed due to the abrupt current fluctuation, to the state where is the ΔSOCvk calculated by the voltage estimate method is mainly employed.

Such a situation may include, for example, a case where the loading rate of 95% or higher calculated at the preceding cycle has dropped to the loading rate of 5% or lower as result of calculation at the latest time.

As already described, the first loading rate is the loading rate equal to or higher than the specified value calculated from the first current range that is assumed to deteriorate the SOC calculation accuracy based on the voltage estimate method. The second loading rate is the loading rate equal to or lower than the specified value calculated from the second current range that is assumed to allow the SOC calculation based on the voltage estimate method to be properly performed. In a stable state where the current range used for the calculation of the loading rate A at the latest time is barely observed, the second loading rate may be 0.

Thus, when the loading rate sharply changes in one cycle, even if the second loading rate is calculated, the use ratio of the ΔSOCvk calculated by the voltage estimate method is not thereby immediately increased, the second loading rate indicating that the current fluctuation has been stabilized. This is because the state in which SOC calculation accuracy calculated by the voltage estimate method has deteriorated due to the abrupt current fluctuation has not yet been converged, and therefore there is a concern that many inaccurate SOC may still be contained.

When the loading rate A have changed from the first loading rate to the second loading rate is decided at step S406 (Y at S406), the loading rate adjustment unit 210 starts the process of obtaining the converging time Gt.

The loading rate adjustment unit 210 receives the input of the loading rate Az (first loading rate) calculated at the preceding cycle and the temperature (S407), and calculates the converging time Gt based on the correlation between the loading rate Az and the temperature (S408), the converging time Gt being converging time until the deteriorated of the SOC accuracy by the abrupt current fluctuation to converge. The converging time Gt is a time necessary for conversion of gain through feedback control in the voltage estimate method, or conversion of error in transient response originating from parameter error of the equivalent circuit.

FIG. 15 is a graph showing a prescribed correlation between the loading rate Az (first loading rate) at an preceding cycle and the temperature, for obtaining the converging time Gt until deteriorated in accuracy due to abrupt current fluctuation in the voltage estimate method is converged. As shown in FIG. 15, the converging time Gt increases, the lower the temperature is, and the higher the loading rate Az (first loading rate) at the preceding cycle is.

Here, the converging time Gt obtained from the loading rate Az (first loading rate) at the preceding cycle may also be defined as converging time required for recovery of the SOC calculation accuracy based on the voltage estimate method, deteriorated due to the current range used for the calculation of the loading rate Az (first loading rate) at the preceding cycle.

The loading rate adjustment unit 210 contains a graph or a map which can obtain the converging time Gt from a prescribed correlation between the loading rate Az at the preceding cycle and the temperature. By inputting the loading rate Az at the preceding cycle and the temperature to the loading rate adjustment unit 210, the converging time Gt can be obtained by referring the graph or the map. Alternatively, the loading rate adjustment unit 210 may contain, in place of the graph or the map, function calculating means corresponding to the graph or the map.

After calculating the converging time Gt, the loading rate adjustment unit 210 calculates, from the converging time Gt, the number of cycles necessary for the SOC accuracy calculated based on the voltage estimate method to recover, and also calculates a subtraction amount Gw for subtracting the loading rate Az (first loading rate) at the preceding cycle for each cycle (S409).

In this process, the number of cycle Sn is calculated by dividing the converging time Gt by the time interval dt of one cycle, the number of cycles Sn being the number of cycles necessary for the loading rate Az (first loading rate) at the preceding cycle, calculated when the abrupt current fluctuation, to drop to the second loading rate calculated in the stable state (see the following equation).

Sn=Gt/dt

Then the subtraction amount Gw is calculated at the processing of each of the periods (see the following equation), the subtraction amount Gw is the subtraction amount for reducing the loading rate Az (first loading rate) of the preceding cycle calculated when the abrupt current fluctuation took place, to the second loading rate.

Gw={loading rate Az(first loading rate at preceding cycle)−second loading rate}/Sn

Then the loading rate obtained by subtracting the subtraction amount Gw from the loading rate Az (first loading rate) at the preceding cycle is outputted as the adjusted loading rate A′. This process is repeated until the loading rate Az (first loading rate) at the preceding cycle becomes equal to the second loading rate. Accordingly, the loading rate Az (first loading rate) at the preceding cycle calculated when the abrupt current fluctuation took place will hereinafter be referred to as the loading rate to be adjusted Az.

In contrast, in the determination at step S406, when the change of the loading rate A in one period does not meet the criterion specified for step S406, the process from step S407 to step S409 is skipped (S406, N).

Then it is decided, on the basis of the loading rate A calculated at the latest time, whether it is necessary to continue the process of subtracting the subtraction amount Gw from the loading rate to be adjusted Az of the latest time (S410). In other words, it is decided whether the continuation of the process is necessary is decided during the calculation process of the adjusted loading rate A′ which is repeated until the loading rate to be adjusted Az becomes equal to the second loading rate.

In this process, it is decided that the loading rate A calculated at the latest time is a value indicating that the current fluctuation has been stabilized, and that the loading rate to be adjusted Az at this time point has not yet reached the second loading rate.

For the former decision, it is decided that the stability of the current fluctuation is maintained, in other words, the loading rate A calculated at the latest time is equal to or lower than the specified value calculated on the basis of the second current range (second loading rate). For the latter decision, it is decided that the loading rate to be adjusted Az has not reached the second loading rate, in other words, that the converging time Gt has not been reached, the converging time Gt being converging time until the deteriorated of the SOC accuracy by the abrupt current fluctuation to converge.

When the conditions of step S410 are not satisfied (N at S410), the loading rate adjustment unit 210 outputs, as done thus far, the loading rate A of the corresponding cycle calculated at step S405.

In contrast, when the conditions of step S410 are satisfied (Y at S410), it is necessary to subtract the subtraction amount Gw from the loading rate to be adjusted Az of that time point and output the reduced loading rate as the adjusted loading rate A′. However, before doing it, it is decided whether the loading rate A calculated at the corresponding cycle is not higher than the loading rate to be adjusted Az of that time point (S411).

In the case where the loading rate A of the corresponding cycle calculated at step S405 has increased beyond the loading rate to be adjusted Az of that time point (N at S411), it indicates that the use ratio of the SOC calculated by the current integration method has increased. In the case where the loading rate A of the corresponding cycle calculated at step S405 has not increased (Y at S411), it indicates that the process of subtracting the loading rate to be adjusted Az is continued as it is.

In the former case, the loading rate adjustment unit 210 outputs the loading rate A of the corresponding cycle calculated at step S405. Accordingly, since the loading rate to be adjusted Az is no longer used in the process of the subsequent periods, the loading rate to be adjusted Az is initialized to 0 and stored in this state (S413).

In the latter case, the value obtained by subtracting the subtraction amount Gw from the loading rate to be adjusted Az at that time point is outputted as the adjusted loading rate A′ for the corresponding cycle. Then the adjusted loading rate A′ is stored as the loading rate to be adjusted Az to be utilized in the process of the next period (S413).

As described above, the adjusted loading rate A′ is calculated by sequentially and cumulatively subtracting the subtraction amount Gw from the loading rate to be adjusted Az for each cycle, and such adjusted loading rate A′ is outputted as the loading rate. After the calculation of the ΔSOCk (S414) and the calculation of the SOCk (S415), the steps of FIG. 14 as from the acquisition of the voltage, the current, and the temperature (S401) are repeated in the next period. Thus, in each of the periods in the converging time Gt, the loading rate Az is reduced by the subtraction amount Gw so as to obtain the adjusted loading rate A′, and the SOCk is calculated utilizing the adjusted loading rate A′ as weight for the use ratio of the ΔSOCi. Here, it is not necessary to perform steps S408 and S409 at every cycle, and it suffices to perform these steps only in the first cycle after the occurrence of the abrupt current fluctuation, focused on in the fourth embodiment.

As described above, in the fourth embodiment, the use ratio of the SOC calculated by the voltage estimate method is controlled to not to be immediately increased, even though the loading rate A has sharply changed from the first loading rate to the second loading rate. In other words, the use ratio of the SOC calculated by the voltage estimate method is not immediately increased when the current fluctuation has converged. Instead, the converging time Gt is controlled with consideration of SOC calculated by the current integration method, the converging time Gt being converging time until the deteriorated of the SOC accuracy by the abrupt current fluctuation to converge.

Therefore, the cell remaining energy computation in the fourth embodiment can compensate the drawback of the voltage estimate method in which the SOC accuracy is deteriorated due to abrupt current fluctuation.

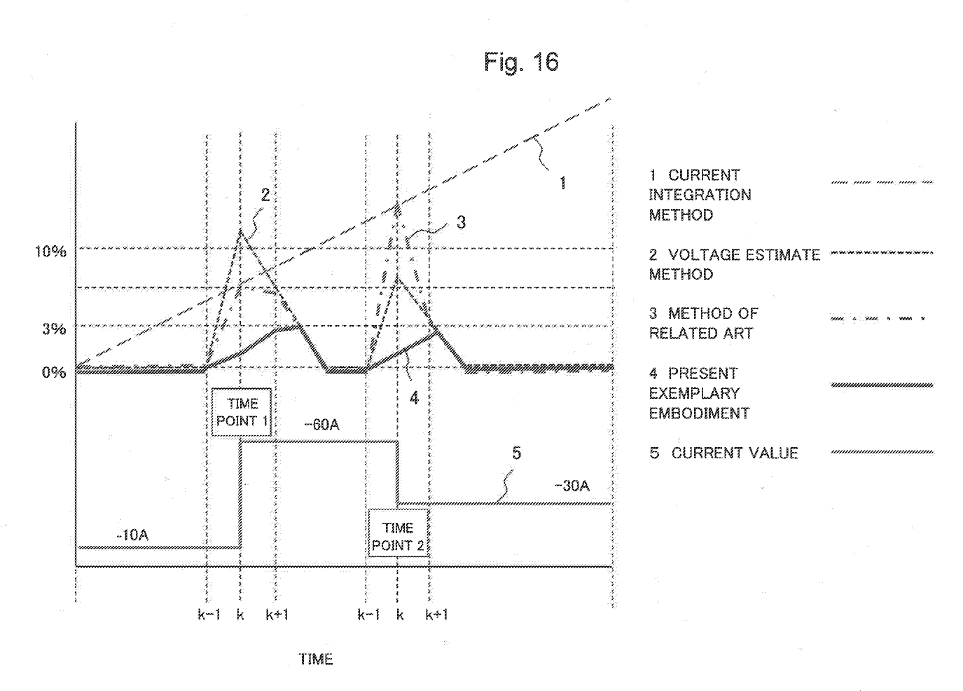

Referring now to FIG. 16, the advantageous effects of the cell remaining energy computation in this embodiment will be described hereunder.

FIG. 16 is a diagram showing differences in errors relative to the SOC true value between the cell remaining energy computation based on the current integration method, the voltage estimate method, and the method according to the related art, and the cell remaining energy computation according to the fourth embodiment of the present invention.

The conditions specified in FIG. 16 are as follows. These conditions are the same as those described for FIG. 12.

In FIG. 16, the horizontal axis represents the lapse of time, and the vertical axis represents the ratio of the error with respect to the true value of the SOC. Here, the true value of the SOC refers to a simulated value obtained by integrating ideal currents free from offset or noise.

In FIG. 16, broken lines denoted by a numeral 1 represent the change of the error in the calculation based on the current integration method, dotted lines denoted by a numeral 2 represent the change of the error in the calculation based on the voltage estimate method, and dash-dot lines denoted by a numeral 3 represent the change of the error in the calculation based on the method of the related art. Solid lines denoted by a numeral 4 indicate the change of the error in the calculation based on the method in this embodiment.

The current fluctuation pattern used for the evaluation is indicated by solid lines denoted by a numeral 5 in the lowermost region of FIG. 16.

The method according to the related art is assumed to be a method that, as disclosed in Patent Literature 1, the SOC calculated by the voltage estimate method is switched to the SOC calculated by the current integration method when abrupt current fluctuation occurs on the battery. In other words, the SOC calculated by the voltage estimate method is utilized until the time k when the abrupt current fluctuation occurs, and the SOC is switched to the SCO calculated by the current integration method at the time k. Then at the time k+1 when the current is stabilized, the SOC is again switched to the SCO calculated by the voltage estimate method.

When solely the current integration method is employed (broken lines of numeral 1), the integration error in the current integration is accumulated with the lapse of time.

When solely the voltage estimate method is employed (dotted lines of numeral 2), the accuracy is deteriorated at the time point when the current has abruptly changed.

In the case of the method according to the related art (dash-dot lines of numeral 3), the SOC is switched to the SOC calculated by the current integration method at the time k when the current has abruptly changed, however the SOC contains the integration error accumulated up to this time point.

The foregoing situation is the same as that of the third embodiment described referring to FIG. 12.

In contrast, with the method in this embodiment (solid lines of numeral 4), the SOC is switched to the SOC calculated by the current integration method at the time point when the current has abruptly changed (time k).

The SOC calculated at this time point only contains period for the most recent one cycle (one second from time k−1 to time k) integration error originating from the current integration, as already pointed out in the description of the first to the third embodiments. Accordingly, the error is suppressed to a low level despite switching to the current integration method.

In addition, at the time point when the current has been stabilized (time k+1), the SOC is supposed to be again switched to the SOC calculated by the voltage estimate method, however by the voltage estimate method it takes time until the SOC accuracy deteriorated at a time point 1 or a time point 2, when the current has abruptly changed, is converged.

Accordingly, during the time between the time k+1 and the time point when the deteriorated accuracy of SOC is converged, the SOC calculated by the current integration method and the SOC calculated by the voltage estimate method are employed at an optimized ratio. At the time k+1, in particular, the ratio of the SOC based on the current integration method is high, and the ratio of the SOC based on the voltage estimate method is increased with the lapse of time within the converging time, as long as the current fluctuation is maintained to be in a stable state.

Therefore, the cell remaining energy computation according to the method in this embodiment provides further improved SOC calculation accuracy, compared with the cell remaining energy computation according to the third embodiment described referring to FIG. 12.

Thus, in this embodiment, when the abrupt current fluctuation has converged the control is executed with consideration the converging time without switching the SOC to the SOC calculated by the voltage estimate method immediately, time until the deteriorated of the SOC accuracy by the abrupt current fluctuation to converge.

In this case, the loading rate calculated at the preceding cycle when the abrupt current fluctuation has occurred is defined as the loading rate to be adjusted. Then the subtraction amount is calculated for each cycle so as to become the loading rate to be adjusted equal to the loading rate indicating the stable state within the converging time. Then the adjusted loading rate is obtained by sequentially and cumulatively subtracting the subtraction amount from the loading rate to be adjusted for each cycle, and such adjusted loading rate is outputted as the loading rate.

In this embodiment, as described above, the SOC calculated by the current integration method and the SOC calculated by the voltage estimate method are employed at an optimized ratio, until the deteriorated SOC accuracy based on the voltage estimate method is converged.

As described thus far, this embodiment can measure the remaining energy with high accuracy, despite combining the calculation method of the remaining energy of the storage cell based on the voltage with the calculation method of the remaining energy of the storage cell based on the current integration.

Here, the hardware configuration of the cell remaining energy computation device in the third embodiment and the fourth embodiment are the same as those in the block diagram illustrated by referring to FIG. 3.

The operations of the cell remaining energy computation devices in the third embodiment and the fourth embodiment may be achieved by mounting therein, circuit parts having hardware components such as an LSI (large scale integration), in which a program for realizing each functions is installed. Such a program may be distributed in the form of a computer-readable recording medium.

In addition, the cell remaining energy computation devices in the third embodiment and the fourth embodiment may be achieved in a form of software, by executing the program that provides each functions of each components, with a CPU of the computer processing device. The program for each of the embodiments serves to cause the computer to act as each functional units specified in the foregoing respective embodiments.

A part or the whole of the foregoing embodiments may be expressed as, but are not limited to, the following supplementary notes.

### (Supplementary Note 1)

A cell remaining energy computation device that acquires a voltage and a current from a storage cell at a prescribed time period, the device comprising:

first computing means that calculates, as a first differential remaining energy, a differential value between a first remaining energy representing a remaining energy of the storage cell at a first time calculated by a voltage estimate method from the voltage and the current of the storage cell acquired at the first time, and a remaining energy of the storage cell at a second time calculated by the voltage estimate method from the voltage and the current of the storage cell acquired at the second time;

second computing means that calculates a second differential remaining energy representing a differential value between the remaining energy of the storage cell at the first time and the remaining energy of the storage cell at the second time, by a current integration method from a current amount integrated during a period between the first time and the second time; and

third computing means that calculates a current range indicating an increase or a decrease of the current, on a basis of the current at the first time and the current at the second time, selects one of the first differential remaining energy or the second differential remaining energy as a differential remaining energy on a basis of the current range, and outputs a sum of the first remaining energy and the selected differential remaining energy, as the remaining energy of the storage cell at the second time.

### (Supplementary Note 2)

The cell remaining energy computation device according to Supplementary Note 1, further comprising: loading rate calculating means that calculates the current range from the current and the temperature acquired from the storage cell in the time period, and calculates a loading rate indicating a use ratio of the second differential remaining energy according to prescribed correlation between the current range and the temperature, wherein the third computing means distributes weight to the first differential remaining energy and the second differential remaining energy according to the loading rate to thereby calculate a third differential remaining energy as a differential remaining energy of the corresponding cycle, adds the third differential remaining energy to the first remaining energy, and outputs the added charges as the remaining energy of the storage cell of the second time.

### (Supplementary Note 3)

The cell remaining energy computation device according to Supplementary Note 2, wherein the loading rate calculating means includes any of a graph or a map that allows the loading rate to be acquired according to prescribed correlation between the current range and the temperature and function calculating means corresponding to the graph or the map.

### (Supplementary Note 4)

The cell remaining energy computation device according to Supplementary Note 2 or 3, further comprising: loading rate adjusting means that receives an input of the loading rate outputted from the loading rate calculating means, calculates a prescribed time interval on a basis of the first loading rate when the loading rate has changed from a first loading rate equal to or higher than a prescribed specified value to a second loading rate equal to or lower than another prescribed specified value, calculates a subtraction amount for each cycle by dividing a differential value between the first loading rate and the second loading rate by the prescribed time interval, calculates an adjusted loading rate obtained by sequentially and cumulatively subtracting the subtraction amount from the first loading rate for each cycle, and outputs the adjusted loading rate as the loading rate.

### (Supplementary Note 5)

The cell remaining energy computation device according to Supplementary Note 4, wherein the prescribed specified value is a loading rate calculated from a first current range that is assumed to deteriorate remaining energy calculation accuracy based on the voltage estimate method; the another specified value is a loading rate calculated from a second current range that is assumed to allow the remaining energy calculation based on the voltage estimate method to be properly performed; and the prescribed time interval is a converging time needed for recovery of the remaining energy calculation accuracy based on the voltage estimate method deteriorated due to the current range used for calculation of the first loading rate.

### (Supplementary Note 6)

The cell remaining energy computation device according to Supplementary Note 5, wherein the converging time is a converging time of gain in the voltage estimate method originating from the current range used for calculation of the first loading rate and is a converging time of error in transient response originating from parameter error of an equivalent circuit; and the loading rate adjusting means includes any of a graph or a map that allows the converging time to be acquired according to prescribed correlation between the first loading rate and the temperature and function calculating means corresponding to the graph or the map.

### (Supplementary Note 7)

A cell remaining energy computation method for acquiring a voltage and a current from a storage cell at a prescribed time period, the method comprising:

first differential remaining energy computing step of calculating, as a first differential remaining energy, a differential value between a first remaining energy representing a remaining energy of the storage cell at a first time calculated based on a voltage estimate method from the voltage and the current of the storage cell acquired at the first time, and a remaining energy of the storage cell at a second time calculated by the voltage estimate method from the voltage and the current of the storage cell acquired at the second time;

second differential remaining energy computing step of calculating a second differential remaining energy representing a differential value between the remaining energy of the storage cell at the first time and the remaining energy of the storage cell at the second time, by a current integration method from a current amount integrated during a period between the first time and the second time; and

storage cell remaining energy computing step of calculating a current range indicating an increase or a decrease of the current, on a basis of the current at the first time and the current at the second time, selecting one of the first differential remaining energy or the second differential remaining energy as a differential remaining energy on a basis of the current range, and outputting a sum of the first remaining energy and the selected differential remaining energy, as the remaining energy of the storage cell at the second time.

### (Supplementary Note 8)

The cell remaining energy computation method according to Supplementary Note 7, further comprising:

loading rate computing step of calculating the current range from the current and the temperature acquired from the storage cell in the time period, and calculating a loading rate indicating a use ratio of the second differential remaining energy according to prescribed correlation between the current range and the temperature, wherein

storage cell remaining energy computing step comprises distributing weight to the first differential remaining energy and the second differential remaining energy according to the loading rate to thereby calculate a third differential remaining energy as a differential remaining energy of the corresponding cycle, adding the third differential remaining energy to the first remaining energy, and outputting the added charges as the remaining energy of the storage cell of the second time.

### (Supplementary Note 9)

The cell remaining energy computation method according to supplementary note 8, wherein the loading rate is calculated by using any of a graph or a map that allows the loading rate to be acquired according to prescribed correlation between the current range and the temperature, or a function calculating means corresponding to the graph or the map.

### (Supplementary Note 10)

The cell remaining energy computation method according to supplementary note 8 or 9, further comprising steps of:

receiving an input of the loading rate outputted from the loading rate calculating means;

calculating a prescribed time interval on the basis of the first loading rate when the loading rate has changed from a first loading rate equal to or higher than a prescribed specified value to a second loading rate equal to or lower than another prescribed specified value;

calculating a subtraction amount for each cycle by dividing a differential value between the first loading rate and the second loading rate by the prescribed time interval; and

calculating an adjusted loading rate obtained by sequentially and cumulatively subtracting the subtraction amount from the first loading rate for each cycle and outputting the adjusted loading rate as the loading rate.

### (Supplementary Note 11)

The cell remaining energy computation method according to supplementary note 10, wherein;

the prescribed specified value is a loading rate calculated based on a first current range that is assumed to deteriorate the remaining energy calculation accuracy based on the voltage estimate method;

the another prescribed specified value is a loading rate calculated based on a second current range that is assumed to allow the remaining energy calculation based on the voltage estimate method to be properly performed; and

the prescribed time interval is a converging time needed for recovery of the remaining energy calculation accuracy based on the voltage estimate method deteriorated due to the current range used for the calculation of the first loading rate.

### (Supplementary Note 12)

The cell remaining energy computation method according to supplementary note 11, wherein the converging time is a converging time of gain in the voltage estimate method originating from the current range used for calculation of the first loading rate, and converging time of error in transient response originating from parameter error of an equivalent circuit; and

the converging time is calculated by using any of a graph or a map that allows the converging time to be acquired according to prescribed correlation between the first loading rate and the temperature, and function calculating means corresponding to the graph or the map.

### (Supplementary Note 13)

A computer-readable recording medium containing a cell remaining energy computation program for acquiring a voltage and a current from a storage cell at a prescribed time period, the program being configured to cause a computer to act as:

first computing functional means that calculates, as a first differential remaining energy, a differential value between a first remaining energy representing a remaining energy of the storage cell at a first time calculated by a voltage estimate method from the voltage and the current of the storage cell acquired at the first time, and a remaining energy of the storage cell at a second time calculated by the voltage estimate method from the voltage and the current of the storage cell acquired at the second time;

second computing functional means that calculates a second differential remaining energy representing a differential value between the remaining energy of the storage cell at the first time and the remaining energy of the storage cell at the second time, by a current integration method from a current amount integrated during a period between the first time and the second time; and

third computing functional means that calculates a current range indicating an increase or a decrease of the current, on a basis of the current at the first time and the current at the second time, selects one of the first differential remaining energy or the second differential remaining energy as a differential remaining energy on a basis of the current range, and outputs a sum of the first remaining energy and the selected differential remaining energy, as the remaining energy of the storage cell at the second time.

### (Supplementary Note 14)

The computer-readable recording medium containing the cell remaining energy computation program according to Supplementary Note 9, the program being configured to cause a computer to act as:

loading rate calculating functional means that calculates the current range from the current and the temperature acquired from the storage cell in the time period, and calculates a loading rate indicating a use ratio of the second differential remaining energy according to prescribed correlation between the current range and the temperature; wherein

the third computing functional means distributes weight to the first differential remaining energy and the second differential remaining energy according to the loading rate to thereby calculate a third differential remaining energy as a differential remaining energy of the corresponding cycle, adds the third differential remaining energy to the first remaining energy, and outputs the added v as the remaining energy of the storage cell of the second time.

### (Supplementary Note 15)

The computer-readable recording medium containing the cell remaining energy computation program according to supplementary note 14, wherein the loading rate calculating functional means includes any of a graph or a map that allows the loading rate to be acquired according to prescribed correlation between the current range and the temperature, and function calculating functional means corresponding to the graph or the map.

### (Supplementary Note 16)

The computer-readable recording medium containing the cell remaining energy computation program according to supplementary note 14 or 15, further comprising:

loading rate adjusting functional means that receives the input of the loading rate outputted from the loading rate calculating functional means, calculates a prescribed time interval on the basis of the first loading rate when the loading rate has changed from a first loading rate equal to or higher than a prescribed specified value to a second loading rate equal to or lower than another prescribed specified value, calculates a subtraction amount for each cycle by dividing a differential value between the first loading rate and the second loading rate by the prescribed time interval, calculates an adjusted loading rate obtained by sequentially and cumulatively subtracting the subtraction amount from the first loading rate for each cycle, and outputs the adjusted loading rate as the loading rate.

### (Supplementary Note 17)

The computer-readable recording medium containing the cell remaining energy computation program according to supplementary note 16, wherein the prescribed specified value is a loading rate calculated based on a first current range that is assumed to deteriorate the remaining energy calculation accuracy based on the voltage estimate method, the another specified value is a loading rate calculated from a second current range that is assumed to allow the remaining energy calculation based on the voltage estimate method to be properly performed, and the prescribed time interval is a converging time needed for recovery of the remaining energy calculation accuracy based on the voltage estimate method deteriorated due to the current range used for the calculation of the first loading rate.

### (Supplementary Note 18)

The computer-readable recording medium containing the cell remaining energy computation program according to supplementary note 17, wherein;

the converging time is a converging time of gain in the voltage estimate method originating from the current range used for calculation of the first loading rate, and is a converging time of error in transient response originating from parameter error of an equivalent circuit; and

the loading rate adjusting functional means includes any of a graph or a map that allows the converging time to be acquired according to prescribed correlation between the first loading rate and the temperature, and function calculating functional means corresponding to the graph or the map.

The present invention has been described as above, with reference to the embodiments. However, the present invention is in no way limited to the foregoing embodiments. Various aspects that could be conceived by persons skilled in the art can be applied to the present invention within the scope of the present invention.

This application claims priority based on Japanese Patent Application No. 2014-185039 filed on Sep. 11, 2014, the entire content of which is incorporated hereinto by reference.

### REFERENCE SIGNS LIST

1, 2, 10, 20 Cell remaining energy computation device
3 Storage cell
4 Energy storage unit
11 First computing means
12 Second computing means
13, 15 Third computing means
14 Loading rate calculating means
21 CPU
22 Main storage unit
23 Auxiliary storage unit
24 External interface unit
25 Display unit
26 Input unit
27 System bus
31 First computing functional means
32 Second computing functional means
33, 35 Third computing functional means
34 Loading rate calculating functional means
101, 201 Voltage acquisition unit
102, 202 Current acquisition unit
103, 203 Temperature acquisition unit
104, 204 SOCv calculation unit
105, 205 ΔSOCv calculation unit
106, 206 ΔSOCi calculation unit
107, 207 Balance calculation unit
108, 208 ΔSOC calculation unit
109, 209 SOC calculation unit
210 Loading rate adjustment unit

1.-10. (canceled)

11. A cell remaining energy computation device that acquires a voltage and a current from a storage cell at a prescribed time cycle, the device comprising:
first computing unit configured to calculate a differential value between a first remaining energy and a remaining energy of the storage cell at a second time as a first differential remaining energy, the first remaining energy indicating a remaining energy at the first time by a voltage estimate method from the voltage and the current of the storage cell;
second computing unit configured to calculate a second differential remaining energy based on an integration amount of current during the period between the first time and the second time, the second differential remaining energy indicating a differential value between the remaining energy of the storage cell at the first time and the remaining energy of the storage cell at the second time; and
third computing unit configured to calculate a current range indicating an increase or a decrease of the current based on the current at the first time and the current at the second time, select one of the first differential remaining energy or the second differential remaining energy as a differential remaining energy based on the current range, and output a sum of the first remaining energy and the selected differential remaining energy, as the remaining energy of the storage cell at the second time.

12. The cell remaining energy computation device according to claim 11, further comprising:
loading rate calculating unit configured to calculate the current range from the current and the temperature which are acquired from the storage cell in the time cycle, and calculate a loading rate based on prescribed correlation between the current range and the temperature, the loading rate indicating a use ratio of the second differential remaining energy;
wherein the third computing unit configured to distribute weight to the first differential remaining energy and the second differential remaining energy by the loading rate to thereby calculate a third differential remaining energy as a differential remaining energy of the corresponding cycle, add the third differential remaining energy to the first remaining energy, and output the added charges as the remaining energy of the storage cell of the second time.

13. The cell remaining energy computation device according to claim 12, wherein
the loading rate calculating unit configured to include a graph or a map each of which can obtain the load rate from the prescribed correlation between the current range, and the temperature and function calculating means corresponding to the graph or the map.

14. The cell remaining energy computation device according to claim 12, further comprising:
loading rate adjusting unit configured to receive an input of the loading rate outputted from the loading rate calculating unit,
calculate a prescribed time interval on a basis of the first loading rate when the loading rate has changed from a first loading rate equal to or higher than a prescribed specified value to a second loading rate equal to or lower than another prescribed specified value,
calculate a subtraction amount for each cycle by dividing a differential value between the first loading rate and the second loading rate by the prescribed time interval,
calculate an adjusted loading rate obtained by sequentially and cumulatively subtracting the subtraction amount from the first loading rate for each cycle, and
output the adjusted loading rate as the loading rate.

15. The cell remaining energy computation device according to claim 14, wherein
the prescribed specified value is a loading rate calculated from a first current range which is considered to degrade calculation accuracy of remaining energy calculated by the voltage estimate method;
the another specified value is a loading rate calculated from a second current range which is considered to execute the calculation of the remaining energy properly; and
the prescribed time interval is a converging time needed for recovery of the remaining energy calculation accuracy of the voltage estimate method deteriorated due to the current range used for calculation of the first loading rate.

16. The cell remaining energy computation device according to claim 15, wherein
the converging time is a converging time of gain in the voltage estimate method due to the current range used for calculation of the first loading rate, and is a converging time of error in transient response originating from parameter error of an equivalent circuit; and
the loading rate adjusting unit configured to include any of a graph or a map which can obtain the conversing time from prescribed correlation between the first loading rate and the temperature, and function calculating means corresponding to the graph or the map.

17. A cell remaining energy computation method for acquiring a voltage and a current from a storage cell at a prescribed time cycle, the method comprising steps of:
calculating a differential value between a first remaining energy and a remaining energy of the storage cell at a second time as a first differential remaining energy, the first remaining energy indicating a remaining energy at the first time by a voltage estimate method from the voltage and the current of the storage cell;
calculating a second differential remaining energy based on an integration amount of current during the period between the first time and the second time, the second differential remaining energy indicating a differential value between the remaining energy of the storage cell at the first time and the remaining energy of the storage cell at the second time;
calculating a current range indicating an increase or a decrease of the current based on the current at the first time and the current at the second time;
selecting one of the first differential remaining energy or the second differential remaining energy as a differential remaining energy based on the current range; and
output a sum of the first remaining energy and the selected differential remaining energy, as the remaining energy of the storage cell at the second time.

18. The cell remaining energy computation method according to claim 17, further comprising steps of:
calculating the current range from the current and the temperature acquired from the storage cell in the time period;
calculating a loading rate indicating a use ratio of the second differential remaining energy according to prescribed correlation between the current range and the temperature;
distributing weight to the first differential remaining energy and the second differential remaining energy according to the loading rate to thereby calculate a third differential remaining energy as a differential remaining energy of the corresponding cycle;
adding the third differential remaining energy to the first remaining energy; and
outputting the added charges as the remaining energy of the storage cell of the second time.

19. The cell remaining energy computation method according to claim 18, further comprising:
referring a map or a graph which can obtain the conversing time from prescribed correlation between the first loading rate and the temperature.

20. The cell remaining energy computation method according to claim 18, further comprising steps of:
receiving an input of the loading rate;
calculating a prescribed time interval on the basis of the first loading rate when the loading rate has changed from a first loading rate equal to or higher than a prescribed specified value to a second loading rate equal to or lower than another prescribed specified value;
calculating a subtraction amount for each cycle by dividing a differential value between the first loading rate and the second loading rate by the prescribed time interval;
calculating an adjusted loading rate obtained by sequentially and cumulatively subtracting the subtraction amount from the first loading rate for each cycle; and
outputting the adjusted loading rate as the loading rate.

21. The cell remaining energy computation method according to claim 20, wherein
the prescribed specified value is a loading rate calculated from a first current range which is considered to degrade calculation accuracy of remaining energy calculated by the voltage estimate method;
the another specified value is a loading rate calculated from a second current range which is considered to execute the calculation of the remaining energy properly; and
the prescribed time interval is a converging time needed for recovery of the remaining energy calculation accuracy of the voltage estimate method deteriorated due to the current range used for calculation of the first loading rate.

22. The cell remaining energy computation method according to claim 21, wherein
the converging time is a converging time of gain in the voltage estimate method due to the current range used for calculation of the first loading rate, and is a converging time of error in transient response originating from parameter error of an equivalent circuit; and
the converging time is calculated by using any of a graph or a map which can obtain the conversing time from prescribed correlation between the first loading rate and the temperature, and function calculating means corresponding to the graph or the map.

23. A non-transitory computer-readable recording medium containing a cell remaining energy computation program for acquiring a voltage and a current from a storage cell at a prescribed time cycle, the program being configured to execute a computer to:
calculating a differential value between a first remaining energy and a remaining energy of the storage cell at a second time as a first differential remaining energy, the first remaining energy indicating a remaining energy at the first time by a voltage estimate method from the voltage and the current of the storage cell;
calculating a second differential remaining energy based on an integration amount of current during the period between the first time and the second time, the second differential remaining energy indicating a differential value between the remaining energy of the storage cell at the first time and the remaining energy of the storage cell at the second time;
calculating a current range indicating an increase or a decrease of the current based on the current at the first time and the current at the second time;
selecting one of the first differential remaining energy or the second differential remaining energy as a differential remaining energy based on the current range; and
output a sum of the first remaining energy and the selected differential remaining energy, as the remaining energy of the storage cell at the second time.

24. The non-transitory computer-readable recording medium containing the cell remaining energy computation program according to claim 23, the program being configured to execute a computer to:
calculating the current range from the current and the temperature acquired from the storage cell in the time period;
calculating a loading rate indicating a use ratio of the second differential remaining energy according to prescribed correlation between the current range and the temperature;
distributing weight to the first differential remaining energy and the second differential remaining energy according to the loading rate to thereby calculate a third differential remaining energy as a differential remaining energy of the corresponding cycle;
adding the third differential remaining energy to the first remaining energy; and
outputting the added charges as the remaining energy of the storage cell of the second time.

25. The non-transitory computer-readable recording medium containing the cell remaining energy computation program according to claim 24, wherein
the converging time is a converging time of gain in the voltage estimate method due to the current range used for calculation of the first loading rate, and is a converging time of error in transient response originating from parameter error of an equivalent circuit; and
the converging time is calculated by using any of a graph or a map which can obtain the conversing time from prescribed correlation between the first loading rate and the temperature, and function calculating means corresponding to the graph or the map.

26. The computer-readable recording medium containing the cell remaining energy computation program according to claim 24, further comprising:
receiving an input of the loading rate;
calculating a prescribed time interval on the basis of the first loading rate when the loading rate has changed from a first loading rate equal to or higher than a prescribed specified value to a second loading rate equal to or lower than another prescribed specified value;
calculating a subtraction amount for each cycle by dividing a differential value between the first loading rate and the second loading rate by the prescribed time interval;
calculating an adjusted loading rate obtained by sequentially and cumulatively subtracting the subtraction amount from the first loading rate for each cycle; and
outputting the adjusted loading rate as the loading rate.

27. The non-transitory computer-readable recording medium containing the cell remaining energy computation program according to claim 26, wherein
the prescribed specified value is a loading rate calculated from a first current range which is considered to degrade calculation accuracy of remaining energy calculated by the voltage estimate method;
the another specified value is a loading rate calculated from a second current range which is considered to execute the calculation of the remaining energy properly; and
the prescribed time interval is a converging time needed for recovery of the remaining energy calculation accuracy of the voltage estimate method deteriorated due to the current range used for calculation of the first loading rate.

28. The non-transitory computer-readable recording medium containing the cell remaining energy computation program according to claim 27, wherein;
the converging time is a converging time of gain in the voltage estimate method due to the current range used for calculation of the first loading rate, and is a converging time of error in transient response originating from parameter error of an equivalent circuit; and
the converging time is calculated by using any of a graph or a map which can obtain the conversing time from prescribed correlation between the first loading rate and the temperature, and function calculating means corresponding to the graph or the map.
